(19) United States
(12) Patent Application Publication
(10) Pub. No.: US 2020/0301056 A1
(43) Pub. Date: Sep. 24, 2020

(54) LONG PHASE DIFFERENCE FILM, LONG LAMINATE, AND IMAGE DISPLAY DEVICE

(71) Applicant: FUJIFILM Corporation, Tokyo (JP)

(72) Inventor: Yoshiaki HISAKADO, Kanagawa (JP)

(73) Assignee: FUJIFILM Corporation, Tokyo (JP)

(21) Appl. No.: 16/890,239

(22) Filed: Jun. 2, 2020

Related U.S. Application Data
(63) Continuation of application No. PCT/JP2018/044529, filed on Dec. 4, 2018.

(30) Foreign Application Priority Data
Dec. 7, 2017 (JP) 2017-235139
Sep. 21, 2018 (JP) 2018-177721

(51) Int. Cl. G02B 5/30

(52) U.S. Cl. CPC G02B 5/3016

(57) ABSTRACT

Provided are a long phase difference film capable of suppressing occurrence of reddish unevenness over time, and a high-quality long laminate and a high-quality image display device, each using the same. The long phase difference film includes a long support and a long optically anisotropic layer arranged on one surface side of the long support, in which the long support has a thickness of 10 μm to 50 μm, a width-direction elastic modulus of 4.3 GPa to 6.0 GPa, and a width-direction coefficient of linear thermal expansion of 20×10⁻⁶/° C. to 40×10⁻⁶/° C., the optically anisotropic layer is formed of a polymerizable liquid crystal composition including a polymerizable liquid crystal compound having reciprocal wavelength dispersion, and an in-plane phase difference change ΔRe at the time of treating a section of the long phase difference film under a heating condition of 85° C. and 500 hours is 0.94 to 1.02.

### CROSS-REFERENCE TO RELATED APPLICATIONS

This application is a Continuation of PCT International Application No. PCT/JP2018/044529 filed on Dec. 4, 2018, which claims priority under 35 U.S.C. § 119(a) to Japanese Patent Application No. 2017-235139 filed on Dec. 7, 2017 and Japanese Patent Application No. 2018-177721 filed on Sep. 21, 2018. Each of the above applications is hereby expressly incorporated by reference, in its entirety, into the present application.

### BACKGROUND OF THE INVENTION

### 1. Field of the Invention

The present invention relates to a long phase difference film, a long laminate, and an image display device.

### 2. Description of the Related Art

In the related art, a polarizing plate having a phase difference film and a polarizer has been used for a liquid crystal display device, an organic electroluminescent device, or the like for the purpose of optical compensation, antireflection, or the like. These are generally manufactured in a roll-to-roll process in order to achieve high productivity and stable quality.

In recent years, development of a polarizing plate (so-called broadband polarizing plate) which can provide similar effects in correspondence to light rays at all wavelengths to those of white light which is at a composite wave having light rays in the visible region coexisting therein has been in progress, and in particular, in view of a demand for reduction in a thickness of a device to which a polarizing plate is applied, reduction in the thickness of a phase difference film included in the polarizing plate has also been demanded.

In response to the above demands, for example, WO2014/010325A and JP2011-207765A each propose a use of a polymerizable liquid crystal compound having reciprocal wavelength dispersion as a polymerizable compound which is used for forming a phase difference film.

### SUMMARY OF THE INVENTION

A phase difference film formed using the polymerizable liquid crystal (polymerizable liquid crystal compound) having reciprocal wavelength dispersion described in WO2014/010325A and JP2011-207765A can provide an excellent broadband polarizing plate with a small number of layers.

However, it has been found that in a case where a polarizing plate having a phase difference film (corresponding to an optically anisotropic layer) formed using a polymerizable liquid crystal (polymerizable liquid crystal compound) having reciprocal wavelength dispersion on a thin resin film (support) having a thickness of 50 μm or less is manufactured, and the polarizing plate is interposed between glasses from both sides and exposed for a long period of time under the condition of a high temperature in accordance with a practical mode (for example, a mode in which the polarizing plate is used as a circularly polarizing plate for the purpose of antireflection of an organic electroluminescent type smartphone), reddish unevenness occurs in the in-plane central portion.

According to the studies of the present inventors, it has been found that a retardation (Re) of a phase difference film significantly varies in a region in which reddish unevenness occurs, thereby causing a change in a tint.

An object of the present invention is to provide a long phase difference film capable of suppressing occurrence of reddish unevenness over time, a long laminate, and an image display device while solving the problems.

In order to accomplish the object, the present invention has the following configuration.

[1] A long phase difference film comprising a long support formed of a resin film; and a long optically anisotropic layer arranged on one surface side of the long support, in which the long support has a thickness of 10 μm to 50 μm, a width-direction elastic modulus of 4.3 GPa to 6.0 GPa, and a width-direction coefficient of linear thermal expansion of 20×10⁻⁶/° C. to 40×10⁻⁶/° C., the optically anisotropic layer is formed of a polymerizable liquid crystal composition including a polymerizable liquid crystal compound having reciprocal wavelength dispersion, and an in-plane phase difference change ΔRe at the time of treating a section of the long phase difference film under a heating condition of 85° C. and 500 hours is 0.94 to 1.02.

[2] The long phase difference film according to [1], in which a width-direction elastic modulus at 140° C. of the long support is 1.5 GPa to 3.0 GPa.

[3] The long phase difference film according to [1] or [2], in which an Re(550) and an Rth(550) of the long support are 0 nm to 10 nm and −20 nm to 40 nm, respectively.

[4] The long phase difference film according to any one of [1] to [3], comprising an alignment layer between the long support and the long optically anisotropic layer, the alignment layer being in contact with the optically anisotropic layer.

[5] The long phase difference film according to any one of [1] to [4], in which an Re(550) of the optically anisotropic layer is 100 nm to 250 nm.

[6] The long phase difference film according to [5], in which an Re(550) of the optically anisotropic layer is 100 nm to 160 nm and an in-plane slow axis of the optically anisotropic layer forms an angle of 30° to 50° with respect to a longitudinal direction of the long support.

[7] The long phase difference film according to any one of [1] to [6],

in which the optically anisotropic layer is in contact with the long support, or

an alignment layer is included between the long support and the optically anisotropic layer, the alignment layer being in contact with the optically anisotropic layer, and

the optically anisotropic layer is provided to be peelable.

[8] A long laminate formed by laminating the long phase difference film according to any one of [1] to [7] and a long linearly polarizing film.

[9] An image display device comprising a polarizing plate cut out from the long laminate according to [8].

[10] A method for producing a long phase difference film, comprising

an applying step of forming a coating film by applying a polymerizable liquid crystal composition including a polymerizable liquid crystal compound having reciprocal wavelength dispersion onto one surface of a long support formed of a resin film while transporting the long support in the longitudinal direction; and

a curing step of curing the coating film to form an optically anisotropic layer,

in which the long support has a thickness of 10 μm to 50 m, a width-direction elastic modulus of 4.3 GPa to 6.0 GPa, and a width-direction coefficient of linear thermal expansion of 10 ppm/° C. to 35 ppm/° C., and

in the curing step, the coating film is cured while heating the coating film to a temperature from 80° C. to 140° C.

According to the present invention, it is possible to provide a long phase difference film capable of suppressing occurrence of reddish unevenness over time, and a high-quality polarizing plate and a high-quality image display device, each using the same.

### DESCRIPTION OF THE PREFERRED EMBODIMENTS

Hereinafter, a long phase difference film, a long laminate, and an image display device of embodiments of the present invention will be described.

Furthermore, in the present specification, a numerical range expressed using “to” means a range that includes the preceding and succeeding numerical values of “to” as the lower limit value and the upper limit value, respectively.

Moreover, “orthogonal” and “parallel” with respect to angles mean a range of a strict angle ±10°, and “same” and “different” with respect to the angles can be determined based on whether the difference is less than 5° or not.

Furthermore, in the present specification, “visible light” means light at 380 to 780 nm. In addition, in the present specification, a measurement wavelength is 550 nm unless otherwise specified.

Next, terms used in the present specification will be described.

<Slow Axis>

In the present specification, a term “slow axis” means a direction in which the in-plane refractive index becomes maximum. In addition, the slow axis of the phase difference film is intended to mean a slow axis of the entire phase difference film.

<Re(λ) and Rth(λ)>

The values of an in-plane retardation and a thickness-direction retardation refer to values measured using AxoScan OPMF-1 (manufactured by Opto Science, Inc.) with a use of light at a measurement wavelength.

Specifically, by inputting an average refractive index ((Nx+Ny+Nz)/3) and a film thickness (d (μm)) to AxoScan OPMF-1, it is possible to calculate:

Slow Axis Direction (°)

Re(λ)=R0(λ)

Rth(λ)=((nx+ny)/2−nz)×d.

In addition, R0(λ) is expressed in a numerical value calculated with AxoScan OPMF-1, and means Re(λ).

[Long Phase Difference Film]

The long phase difference film of an embodiment of the present invention includes at least a long optically anisotropic layer formed using a polymerizable liquid crystal composition on a long support.

The long support has a thickness of 10 μm to 50 μm, a width-direction elastic modulus of 4.3 GPa to 6.0 GPa, and a width-direction coefficient of linear thermal expansion of 10 ppm/° C. to 35 ppm/° C.

The optically anisotropic layer is formed of a polymerizable liquid crystal composition including a polymerizable liquid crystal compound having reciprocal wavelength dispersion.

An in-plane phase difference change ΔRe in a case where a section of the long phase difference film is treated under a heating condition of 85° C. and 500 hours is 0.94 to 1.02.

By cutting the long phase difference film of the embodiment of the present invention into a desired size, a sheet-like phase difference film can be obtained. Therefore, in the present specification, in a case where a phase difference film or an optically anisotropic layer is simply referred, there is no particular distinction between a long shape and a sheet-like shape unless otherwise specified. In addition, it is not necessary that various physical properties and characteristics relating to the phase difference film and the optical anisotropy described which will be below are completely uniform in the entire region of the long phase difference film, and in particular, unless not specified, they should be applied to a portion which can be used in accordance with the original purpose and/or function in the long film.

The long phase difference film of the embodiment of the present invention is applicable to various image display devices, but is particularly preferably used for an organic EL display device.

As described above, the phase difference film formed using the polymerizable liquid crystal compound having reciprocal wavelength dispersion can provide an excellent broadband polarizing plate with a small number of layers. However, it was found that in a case where a phase difference film having an optically anisotropic layer formed using a polymerizable liquid crystal compound having reciprocal wavelength dispersion on a thin resin film (support) having a thickness of 50 μm or less is used for an image display device, a problem of generation of reddish unevenness occurs over time.

According to the studies of the present inventors, it has been found that a retardation (Re) of a phase difference film significantly varies in a region in which reddish unevenness occurs, thereby causing a change in a tint. According to further studies on this point which had been carried out, it has been found that a reason of the significant variation in the retardation (Re) of the phase difference film is deterioration of the optically anisotropic layer by heat, humidity, or aging since the polymerization reaction rate of the polymerizable liquid crystal compound in the liquid crystal layer in the optically anisotropic layer is low.

In a case where an optically anisotropic layer having reciprocal wavelength dispersion is formed using a polymerizable liquid crystal compound having reciprocal wavelength dispersion, it is necessary to reduce the amount of the polymerization initiator. This is because an increase in the amount of the polymerization initiator results in formation of an optically anisotropic layer having forward dispersion. However, in a case where the amount of the polymerization initiator is reduced, the polymerization reaction rate of the polymerizable liquid crystal compound in the optically anisotropic layer remains relatively low. As a result, the alignment of the liquid crystal molecules is relaxed due to various decompositions or external factors in the chemical structure and the optically anisotropic layer is deteriorated by heat, humidity, or aging. It was found that such deterioration results in variation of the retardation (Re) of the phase difference film varies and occurrence of a problem of occurrence of reddish unevenness.

Here, the present inventors have found that the polymerization reaction rate of the polymerizable liquid crystal compound can be increased and the durability of an optically anisotropic layer thus formed can be improved by performing a curing treatment for fixing the alignment of the polymerizable liquid crystal compound at a high temperature even in a case where the amount of the polymerization initiator is reduced.

However, in a case where a thin resin film is used as the support, it is difficult to perform sufficient heating to increase the polymerization reaction rate since the resin film may be stretched by heating and wrinkles may be generated.

In particular, in a case where a roll-to-roll process is performed so as to produce a long phase difference film, it is necessary to pay close attention to heating conditions in order to maintain the obtained alignment state obtained by performing a liquid crystal alignment treatment before the curing treatment. The present inventors have conducted various studies on such a continuous heating and curing process, and have thus found that the long support deflects in the width direction while being under heating and curing conditions for improving the durability of the optically anisotropic layer, and deformation such as wrinkles and deflections and remarkable unevenness of the optical characteristics occur in a long phase difference film obtained by performing a curing treatment leaving the deflection as it is.

It is presumed that the long support thermally expands by heating and the stress is combined with various stresses related to the transport of the long support, and as a result, in a case where the stress applied in the width direction of the long support exceeds the rigidity of the long support, the long support buckles, causing deflection.

The present inventors have conducted intensive studies in order to solve two problems of improving durability and generating optical unevenness, and as a result, they have found that in a case where a phase difference film having excellent optical characteristics and durability can be provided by applying a specific long support in a case of using a polymerizable liquid crystal composition having reciprocal wavelength dispersion; and a high-quality phase difference film having no unevenness in optical characteristics in a roll-to-roll process can be obtained.

That is, in the long phase difference film of the embodiment of the present invention, a width-direction elastic modulus and a width-direction coefficient of linear thermal expansion of the long support are 4.3 GPa to 6.0 GPa and 10 ppm/° C. to 35 ppm/° C., respectively. By setting the width-direction coefficient of linear thermal expansion of the long support to be within the above range and by increasing the width-direction elastic modulus of the long support to secure rigidity in the width direction, it is possible to obtain a long phase difference film having excellent productivity with high quality without various unevenness caused by deflection, wrinkles of the long support, and breakage even in a case where a polymerizable liquid crystal composition having reciprocal wavelength dispersion that is preferably heated at the time curing is applied to a thin long support.

In addition, even in a case of using the heating and curing conditions for improving the durability of the optically anisotropic layer, the long support can be suppressed from deflection in the width direction, and therefore, the polymerization reaction rate of the polymerizable liquid crystal compound can be increased, and thus, the durability can be improved. Specifically, an in-plane phase difference change ΔRe in a case where the section of the long phase difference film is treated under a heating condition of 85° C. and 500 hours can be reduced to 0.94 to 1.02.

That is, such the long phase difference film of the embodiment of the present invention is an excellent phase difference film which has a small phase difference value or a small dimensional change even under the conditions of the durability test.

The long phase difference film of the embodiment of the present invention has a small in-plane phase difference change ΔRe of 0.94 to 1.02, and even in a case of being incorporated in an image display device or the like, the retardation (Re) of the phase difference film hardly varies due to heat, humidity, aging, or the like, and therefore, it is possible to suppress the occurrence of reddish unevenness in the in-plane central portion.

Here, the in-plane phase difference change ΔRe is represented by the following equation from an in-plane phase difference Rea(550) between before a treatment of the section of the long phase difference film under the heating condition of 85° C. and 500 hours and an in-plane phase difference Reb(550) after the treatment of the section.

ΔRe=|Rea(550)−Reb(550)|+|Rea(550)|

Here, Rea(550) and Reb(550) are each an in-plane phase difference of the section of the phase difference film at a measurement wavelength of 550 nm.

In addition, the section of the phase difference film is a sample having a size of 140 mm×70 mm cut out from an arbitrary position of the long phase difference film.

From the viewpoint that reddish unevenness can be more suitably suppressed, the in-plane phase difference change ΔRe is more preferably 0.96 to 1.01.

A thickness of the phase difference film is preferably 100 μm or less, more preferably 50 μm or less, and still more preferably 25 μm or less, from the viewpoint of reducing the thickness of the member. From the viewpoint of production suitability, the thickness is preferably 5 μm or more, more preferably 10 μm or more, and still more preferably 15 μm or more. In addition, in a case where the phase difference film has a plurality of layers, the thickness of the phase difference film indicates a total entire thickness including the layers.

A length of the long phase difference film can be 100 m to 10,000 m, and is preferably 250 m to 7,000 m, and more preferably 1,000 m to 6,000 m. Further, the width can be 400 to 3,000 mm, and is preferably 500 to 2,500 mm, and more preferably 600 to 1,750 mm. Within this range, the economy in the roll-to-roll process can be enhanced and a long phase difference film having excellent uniformity in the longitudinal and width directions can be produced.

Moreover, the long phase difference film of the embodiment of the present invention is not limited to the configuration including the long support and the optically anisotropic layer, and may have another layer. Further, the configuration is not limited to a configuration in which the optically anisotropic layer is directly formed on the long support, and another layer may be provided between the long support and the optically anisotropic layer. For example, an alignment layer may be provided between the long support and the optically anisotropic layer, the alignment layer being in contact with the optically anisotropic layer.

The alignment layer (alignment film) is a layer having a function of defining the alignment direction of the polymerizable liquid crystal compound. By incorporating an alignment layer in contact with the optically anisotropic layer, it is possible to bring the polymerizable liquid crystal compound in the coating film serving as the optically anisotropic layer into a uniform and efficiently preferable alignment state at the time of forming the optically anisotropic layer.

Next, components constituting the long phase difference film of the embodiment of the present invention will be described.

<Long Support>

The long support of the long phase difference film of the embodiment of the present invention has a long shape and is preferably transparent. Specifically, a linear light transmittance in the visible light region is preferably 80% or more. Examples of such a support include a long body of a polymer film. The support is preferably a polymer film since it has both flexibility and strength at the time of being handled as a roll-shaped wound body.

Examples of the resin constituting such a polymer film include celluloses such as cellulose acylate; (meth)acrylic resins such as polymethyl methacrylate and other copolymers of (meth)acrylates; polyolefins such as polystyrene, a fumaric acid polymer, a cycloolefin polymer, polyethylene, and polypropylene; polyesters typified by polyethylene terephthalate; polycarbonates; and copolymers thereof.

Here, as described above, in the long phase difference film of the embodiment of the present invention, the long support has a thickness in a range of 10 μm to 50 μm, a width-direction elastic modulus of 4.3 GPa to 6.0 GPa, and a width-direction coefficient of linear thermal expansion of 20×10⁻⁶/° C. to 40×10⁻⁶/° C.

From the viewpoint of reducing a thickness of the long phase difference film, and the like, the thickness of the long support is preferably 50 μm or less, and more preferably 25 μm or less. On the other hand, from the viewpoints of the supportability of the optically anisotropic layer, generation of wrinkles during handling, and the like, the thickness is preferably 10 μm or more, and more preferably 15 μm or more.

The width-direction elastic modulus of the long support can be determined by measuring an elastic modulus in the direction orthogonal to the longitudinal direction of the long support with Strograph. From the viewpoint that generation of wrinkles and the like in the long support due to heat during formation of the optically anisotropic layer can be suppressed, the width-direction elastic modulus of the long support is preferably 4.3 GPa or more, and more preferably 4.5 GPa or more. On the other hand, from the viewpoint of the flexibility of the long support, the width-direction elastic modulus of the long support is preferably 6.0 GPa or less, and more preferably 5.5 GPa or less.

In addition, the width-direction elastic modulus of the long support is an elastic modulus at normal temperature (25° C.) unless otherwise specified.

Furthermore, the width-direction elastic modulus at 140° C. of the long support is preferably 1.5 GPa to 3.0 GPa, and more preferably 1.7 GPa to 3.0 GPa. By setting the width-direction elastic modulus at 140° C. to be within the range, generation of wrinkles and the like in the long support due to heat during formation of the optically anisotropic layer can be more suitably suppressed.

From the viewpoint of suppressing generation of wrinkles and the like in the long support by heat during formation of the optically anisotropic layer, the width-direction coefficient of linear thermal expansion of the long support is preferably 40×10⁻⁶/° C. or less, and more preferably 38×10⁻⁶/° C. or less. On the other hand, from the viewpoint of the flexibility of the long support, the width-direction coefficient of linear thermal expansion of the long support is preferably 20×10⁻⁶/° C. or more, and more preferably 30×10⁻⁶/° C. or more.

The width-direction coefficient of linear thermal expansion of the long support can be measured by thermal mechanical analysis (TMA).

The optical characteristics of the support can be set to various ones as desired, and in a preferred aspect, the support can be optically isotropic. More specifically, Re(550) can be 0 nm to 10 nm, and is more preferably in a range of 0 nm to 5 nm. Further, Rth(550) can be −20 nm to 40 nm, and is more preferably −10 nm to 20 nm. In addition, in another preferred aspect, Re(550) of the long support is 100 nm to 350 nm, the Nz value is 0.1 to 0.9, and the slow axis can be parallel or orthogonal to the longitudinal direction of the long support.

Examples of the film satisfying the above-mentioned conditions include a cellulose acylate film, a cycloolefin film, a (meth)acrylic resin film, a polyethylene terephthalate film, and a polycarbonate film.

(Cellulose Acylate Film)

As the long support used in the present invention, a cellulose acylate film can be used. This is preferably used from the viewpoint that it has both transparency and strength and can easily control the adhesion to each of layers which will be described later or easy peelability. As the cellulose acylate film, a film which includes a cellulose acylate resin, and as desired, an additive can be used. The cellulose acylate film can be produced by solution film formation or may be produced by melt film formation.

As the cellulose acylate resin, triacetyl cellulose, diacetyl cellulose, and cellulose in which a part of an acetyl group is substituted with a higher acyl group or aromatic acyl group, an alkoxy group, or a substituted alkoxy group can be used. With regard to the cellulose acylate, a degree of substitution of cellulose with hydroxyl groups is not particularly limited, but the degree of acyl substitution of cellulose with hydroxyl groups is preferably 2.00 to 3.00 in order to impart appropriate moisture permeability and hygroscopicity. In addition, the degree of substitution is preferably 2.30 to 2.98, more preferably 2.70 to 2.96, and still more preferably 2.80 to 2.94.

As the additive, for example, various additives described in JP2005-154764A, JP2013-228720A, JP2014-081619A, JP2014-178519A, JP2015-227956A, JP2016-006439A, JP2016-164668A, or JP2017-106975A can be used.

A preferred example of the additive includes a polyester additive having a repeating unit represented by the following general formula.

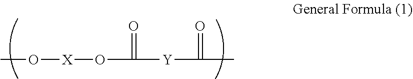

(In General Formula (I), X and Y each represent a divalent linking group.)

X can be an alkylene group having 2 to 20 carbon atoms, which may have a substituent, a polyoxyalkylene group, an alkenylene group, a phenylene group, a naphthylene group, or a heterocyclic aromatic group. In addition, the alkylene group, the alkenylene group, and the polyoxyalkylene group in the above-mentioned alkylene group may have an alicyclic structure.

Y can be an alkylene group having 2 to 20 carbon atoms, which may have a substituent, a polyoxyalkylene group, an alkenylene group, a phenylene group, a naphthylene group, or a heterocyclic aromatic group. In addition, the alkylene group, the alkenylene group, and the polyoxyalkylene group in the above-mentioned alkylene group may have an alicyclic structure.

These divalent linking groups may include a molecule other than carbon, such as an oxygen atom and a nitrogen atom. Examples of the above-mentioned substituent include an alkyl group, an alkoxy group, a hydroxyl group, an alkoxy-substituted alkyl group, and a carboxyl group.

It is preferable that X represents an acyclic divalent linking group having 2 to 10 carbon atoms and Y represents a linking group having 3 to 12 carbon atoms including an alicyclic structure having a 3- to 6-membered ring, as a repeating unit represented by General Formula (I), from the viewpoints of excellent phase difference characteristics and elasticity of the film. The alicyclic structure is the 3- to 6-membered ring, and preferably a 5- to 6-membered ring, and specific examples thereof include a cyclopropylene group, a 1,2-cyclobutylene group, a 1,3-cyclobutylene group, a 1,2-cyclopentylene group, a 1,3-cyclopentylene group, a 1,2-cyclohexylene group, a 1,3-cyclohexylene group, and a 1,4-cyclohexylene group.

The hydrogen atom at the hydroxyl group terminal of the polyester additive having a repeating unit represented by General Formula (I) may be substituted with an acyl group derived from a monocarboxylic acid (hereinafter also referred to as a monocarboxylic acid residue) (hereinafter also referred to as the hydrogen atom at the hydroxyl group terminal being sealed). In this case, both terminals of the polyester are monocarboxylic acid residues. By protecting the terminal with a hydrophobic functional group, the cohesive force of the additive is suppressed, the compatibility with the film and the handling of the compound are improved, and a film having excellent temperature/humidity stability and polarizer durability of the polarizing plate can be obtained.

Here, the residue represents a partial structure of the polyester, which has the characteristics of a monomer forming the polyester. For example, a monocarboxylic acid residue formed from the monocarboxylic acid R—COOH is R—CO—. Examples of R include an alkyl group having 1 to 10 carbon atoms, which may have a substituent, an alicyclic alkyl group, and an aromatic group. The monocarboxylic acid residue is preferably an aliphatic monocarboxylic acid residue, more preferably an aliphatic monocarboxylic acid residue in which the monocarboxylic acid residue has 2 to 10 carbon atoms, still more preferably an aliphatic monocarboxylic acid residue having 2 or 3 carbon atoms, and particularly preferably an aliphatic monocarboxylic acid residue having 2 carbon atoms.

From the viewpoint of improving the polarizer durability, a hydroxyl value of the polyester is preferably 10 mgKOH/g or less, more preferably 5 mgKOH/g or less, and particularly preferably 0 mgKOH/g. Further, the number-average molecular weight (Mw) of the polyester can be 500 to 3,000, and more preferably 700 to 2,000. Within this range, it is possible to obtain a film which has excellent compatibility and is stable with less volatilization of additives during production and use of the film.

Furthermore, as another preferred example of the additive, a compound (sugar ester compound) in which at least one of substitutable groups (for example, a hydroxyl group and a carboxyl group) in a sugar skeleton structure and at least one kind of substituent are ester-bonded can be used. More specifically, a sugar ester compound in which all or a part of the hydroxyl groups (hereinafter referred to as an OH group) of a compound (M) having at least 1 to 12 pyranose or furanose structures or a compound (D) having at least one kind of two furanose or pyranose structures bonded thereto are alkyl esterified is preferably used.

Examples of the compound (M) include glucose, galactose, mannose, fructose, xylose, and arabinose, among which the glucose or the fructose is preferable, and the glucose is more preferable. Examples of the compound (D) include lactose, sucrose, nystose, 1F-fructosylnystose, stachyose, maltitol, lactitol, lactulose, cellobiose, maltose, cellotriose, maltotriose, raffinose, and Stokes. Other examples thereof include gentiobiose, gentiotriose, gentiotetraose, xylotriose, and galactosyl sucrose. Among these, the glucose, the sucrose, or the lactose is preferable.

In order to alkyl-esterify all or a part of the OH groups in the compound (M) and the compound (D), it is preferable to use an aliphatic monocarboxylic acid, a monocarboxylic acid having an alicyclic structure, or an aromatic monocarboxylic acid. Examples of such a monocarboxylic acid include acetic acid, propionic acid, butyric acid, isobutyric acid, benzoic acid, and cyclohexanecarboxylic acid. These monocarboxylic acids may be used in combination of two or more kinds thereof.

As other additives, a plasticizer, an ultraviolet absorber, a crosslinking agent, a matting agent (inorganic fine particles), an antioxidant, a radical scavenger, or the like may be added. In a case where a polarizing plate is configured so that it also serves as a polarizing plate-protective film on a support of the phase difference film of the embodiment of the present invention as described below, it is preferable to further include a compound represented by the following general formula from the viewpoint of imparting an action of improving the durability of the polarizer:

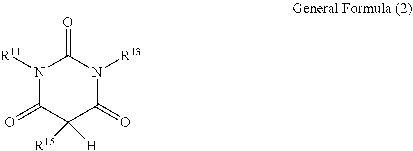

(In General Formula (2), R¹¹, R¹³, and R¹⁵ each independently represent a hydrogen atom, an alkyl group having 1 to 20 carbon atoms, a cycloalkyl group having 3 to 20 carbon atoms, an alkenyl group having 2 to 20 carbon atoms or an aromatic group having 6 to 20 carbon atoms.)

As such a compound, for example, those described in WO2014/112575 can be used.

The cellulose acylate film used in the present invention can be manufactured using the method described in Japan Institute of Invention and Innovation (Hatsumei Kyokai) Disclosure Bulletin (Bulletin No. 2001-1745, Japan Institute of Invention and Innovation) published by Japan Institute of Invention and Innovation.

Such a cellulose acylate film can be obtained by uniaxially or biaxially stretching as necessary, and those stretched in the width direction can be preferably used. Further, the cellulose acylate film may be stretched in an oblique direction. A stretching ratio in one direction can be 1.02 to 1.50, and is preferably 1.05 to 1.30. By performing a stretching treatment, control of physical properties suitable for the purpose of the present invention can be performed.

In the cellulose acylate film, a glass transition temperature can be 140° C. to 200° C., more preferably 160° C. to 190° C., and particularly preferably 170° C. to 185° C. Within this range, the resistance to thermal deflection, which is the object of the present invention, becomes more excellent, and the physical properties can be easily controlled by stretching. The glass transition temperature can be determined as a peak value of tan δ by a dynamic viscoelasticity measuring device.

<Alignment Layer>

The long phase difference film of the embodiment of the present invention may include an alignment film (alignment layer) which has a function of defining the alignment direction of a polymerizable liquid crystal composition forming the optically anisotropic layer. Thus, the polymerizable liquid crystal composition can be uniformly and efficiently derived into a desired alignment state.

Examples of the alignment film include a rubbing-treated film of a layer including an organic compound such as a polymer, an oblique vapor deposition film of an inorganic compound, a film having microgrooves, or a film formed by accumulating a Langmuir-Blodgett (LB) film according to an LB method of an organic compound such as o-tricosanoic acid, dioctadecylmethylammonium chloride, and methyl stearate. Further, an alignment film or the like which has an alignment function generated by light irradiation may also be included.

As the alignment film, a layer (polymer layer) formed by rubbing a surface of a layer including an organic compound such as a polymer can be preferably used. The rubbing treatment is carried out by rubbing a surface of the polymer layer several times with paper or cloth in a certain direction (preferably the longitudinal direction of the support). As the polymer used for formation of the alignment film, polyimide, polyvinyl alcohol, the modified polyvinyl alcohol described in paragraphs [0071] to [0095] of JP3907735B, the polymer having a polymerizable group described in JP1997-152509A (JP-H09-152509A), or the like is preferably used.

Furthermore, in another preferred embodiment, a so-called photo-alignment film (photo-alignment layer), which becomes an alignment layer by irradiating a photo-alignment material with polarized or non-polarized light to form an alignment layer, is used as the alignment film. It is preferable that the photo-alignment film is provided with an alignment regulating force by a step of irradiating polarized light from a vertical or oblique direction or a step of irradiating non-polarized light from an oblique direction. By using the photo-alignment film, it is possible to align a polymerizable liquid crystal compound which will be described below with excellent symmetry.

Examples of the photo-alignment material used for a photo-alignment film include the azo compounds described in JP2006-285197A, JP2007-076839A, JP2007-138138A, JP2007-094071A, JP2007-121721A, JP2007-140465A, JP2007-156439A, JP2007-133184A, JP2009-109831A, JP3883848B, and JP4151746B, the aromatic ester compounds described in JP2002-229039A, the maleimide and/or alkenyl-substituted nadimide compounds having photo-alignment units described in JP2002-265541A and JP2002-317013A, the photocrosslinkable silane derivatives described in JP4205195B and JP4205198B, the photocrosslinkable polyimides, polyamides, and esters described in JP2003-520878A, JP2004-529220A, and JP4162850B, and the photodimerizable compounds, in particular, a cinnamate compound, a chalcone compound, and a coumarin compound, described in JP1997-118717A (JP-H09-118717A), JP998-506420A (JP-H10-506420A), JP2003-505561 A, WO2010/150748A, JP2013-177561A, and JP2014-012823A. Particularly preferred examples of the photo-alignment material include the azo compounds, the photocrosslinkable polyimides, the polyamides, the esters, the cinnamate compounds, and the chalcone compounds.

A thickness of the alignment film is not particularly limited as long as it can exhibit an alignment function, but is preferably 0.01 to 5 μm, and more preferably 0.05 to 2 μm. Within this range, an excellent alignment regulating force can be exhibited and an effect of suppressing foreign matter defects is significant.

The support and the alignment film may be separately provided as layers that perform their respective functions, or the support may also serve as an alignment film, that is, in a mode in which the support surface has an alignment regulating force. Further, in a case where the support and the alignment film are provided separately, the support and the alignment film may be provided in contact with each other, or a functional layer may be interposed between the support and the alignment film. As a means for directly applying an alignment regulating force without providing an alignment film on a surface of the support, an approach in which the surface of the support is subjected to the above-described treatment such as rubbing and polarized light irradiation, and the polymer constituting the support by stretching the support is aligned in a certain direction can be taken. Examples of the above-mentioned functional layer that can be interposed between the support and the alignment film include a barrier layer, an impact relaxation layer, an easily peelable layer, and an easily adhesive layer.

<Optically Anisotropic Layer>

The long phase difference film of an embodiment of the present invention includes at least a long optically anisotropic layer formed using a polymerizable liquid crystal composition on a long support.

The optically anisotropic layer has an in-plane retardation value Re(450) measured at a wavelength of 450 nm, an in-plane retardation value Re(550) measured at a wavelength of 550 nm, and an in-plane retardation value Re(650) measured at a wavelength of 650 nm, which are in a relationship of Re(450)<Re(550)<Re(650). That is, this relationship can be said to be a relationship indicating the above-described reciprocal wavelength dispersion. The optically anisotropic layer having such characteristics can be suitably used as a λ/4 plate which will be described later, various optical functional layers, and optical compensation layers in order to provide uniform polarization conversion characteristics at each wavelength. The in-plane retardation Re(550) can be 100 nm to 350 nm, and more preferably 100 nm to 250 nm.

A method for measuring the in-plane retardation value at each wavelength is as described above.

A thickness of the optically anisotropic layer can be appropriately set in consideration of a refractive index anisotropy of the polymerizable liquid crystal composition used with respect to a desired phase difference, and is, for example, preferably 0.5 μm to 5 μm, more preferably 0.7 μm to 4 μm, and still more preferably 1 μm to 3 μm. Within this range, failures such as a foreign matter and an abnormal alignment are suppressed, and thus, an optically anisotropic layer which has a high in-plane uniformity is robust both on the surface and the inside of the layer and has excellent durability can be obtained.

The polymerizable liquid crystal composition which serves as an optically anisotropic layer contains a polymerizable liquid crystal compound having reciprocal wavelength dispersion. Further, other polymerizable compounds, a leveling agent, a solvent, and other components can be included as necessary.

(Polymerizable Liquid Crystal Compound Having Reciprocal Wavelength Dispersion)

In the present specification, a polymerizable liquid crystal compound having “reciprocal wavelength dispersion” indicates that in a case where a phase difference, typically an in-plane retardation (Re) value, at a specific wavelength (visible region) of a phase difference layer manufactured with the polymerizable liquid crystal compound is measured, the Re value becomes equal or higher as the measurement wavelength increases, and the compound satisfies the relationship of Re(450)<Re(550)<Re(650) as described later. A case where the same relationship is satisfied by Rth(λ) instead of Re(λ) is also included.

In addition, the polymerizable liquid crystal compound in the present specification refers to a liquid crystal compound having a polymerizable group. The type of the polymerizable group of a specific polymerizable liquid crystal compound is not particularly limited, and examples thereof include an acryloyl group, a methacryloyl group, a vinyl group, a styryl group, and an allyl group.

The type of the specific liquid crystal compound is not particularly limited, but the types are classified into a rod-shaped type (rod-shaped liquid crystal compound) and a disk-shaped type (disk-shaped liquid crystal compound, discotic liquid crystal compound) in terms of the shapes. Each of the types can further be classified into a low-molecular-weight type and a high-molecular-weight type. The term, high-molecular-weight, generally refers to having a degree of polymerization of 100 or more (Polymer Physics-Phase Transition Dynamics, by Masao Doi, page 2, published by Iwanami Shoten, Publishers, 1992). In the present invention, any liquid crystal compound can be used. Two or more kinds of the rod-shaped liquid crystal compounds, two or more kinds of the disk-shaped liquid crystal compounds, or a mixture of the rod-shaped liquid crystal compound and the disk-shaped liquid crystal compound may be used.

Among these, the rod-shaped liquid crystal compound is preferably used. The homogenous (horizontal) alignment of the rod-shaped liquid crystal compound has an advantage that a phase difference film thus formed can easily function as a positive A-plate as described later.

The liquid crystal compound having reciprocal wavelength dispersion is not particularly limited as long as it can form a film having reciprocal wavelength dispersion as described above, and for example, the compound represented by General Formula (I) described in JP2008-297210A (in particular, the compound described in paragraph Nos. [0034] to [0039]), the compound represented by General Formula (I) described in JP2010-084032A (in particular, the compound described in paragraph Nos. [0067] to [0073]), a liquid crystal compound represented by General Formula (I) which will be described later, or the like can be used.

The above-mentioned specific liquid crystal compound preferably includes a liquid crystal compound represented by General Formula (II) from the viewpoint of more excellent reciprocal wavelength dispersion.

L₁-G₁-D₁-Ar-D₂-G₂-L₂ General Formula (II)

In General Formula (II), D₁ and D₂ each independently represent a single bond, —CO—O—, —C(═S)O—, —CR¹R²—, —CR¹R²—CR³R⁴—, —O—CR¹R², —CR¹R²—O—CR³R⁴—, —CO—O—CR¹R²—, —O—CO—CR¹R²—, —CR¹R²—O—CO—CR³R⁴—, —CR¹R²—CO—O—CR³R⁴—, —NR¹—CR²R³—, or —CO—NR¹—.

R¹, R², R³, and R⁴ each independently represent a hydrogen atom, a fluorine atom, or an alkyl group having 1 to 4 carbon atoms. In a case where a plurality of R¹, R², R³, and R⁴ are present, the plurality of R¹, the plurality of R², the plurality of R³, and the plurality of R⁴ may be the same as or different from each other.

G₁ and G₂ each independently represent a divalent alicyclic hydrocarbon group having 5 to 8 carbon atoms, and the methylene group contained in the alicyclic hydrocarbon group may be substituted with —O—, —S—, or —NH—.

L₁ and L₂ each independently represent a monovalent organic group, and at least one selected from the group consisting of L₁ and L₂ represents a monovalent group having a polymerizable group.

Ar represents a divalent aromatic ring group represented by General Formula (II-1), (II-2), (II-3), or (II-4).

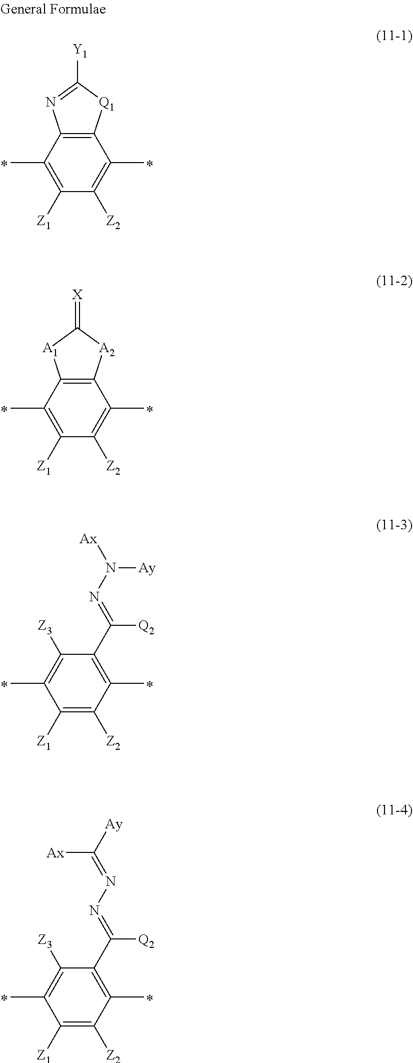

In General Formulae (II-1) to (II-4), Q₁ represents —S—, —O—, or —NR¹¹—,

R¹¹ represents a hydrogen atom or an alkyl group having 1 to 6 carbon atoms,

Y₁ represents an aromatic hydrocarbon group having 6 to 12 carbon atoms or an aromatic heterocyclic group having 3 to 12 carbon atoms (the aromatic hydrocarbon group and the aromatic heterocyclic group each may each have a substituent),

Z₁, Z₂, and Z₃ each independently represent a hydrogen atom or an aliphatic hydrocarbon group having 1 to 20 carbon atoms, an alicyclic hydrocarbon group having 3 to 20 carbon atoms, or a monovalent aromatic hydrocarbon group having 6 to 20 carbon atoms, a hydrogen group, a halogen atom, a cyano group, a nitro group, —NR¹²R¹³, or —SR¹²,

Z₁ and Z₂ may be bonded to each other to form an aromatic ring or an aromatic heterocyclic ring, and R¹² and R¹³ each independently represent a hydrogen atom or an alkyl group having 1 to 6 carbon atoms,

A₁ and A₂ are each independently a group selected from the group consisting of —O—, —NR²¹—, —S—, and —CO—, in which R²¹ represents a hydrogen atom or a substituent, and X represents a hydrogen atom or a non-metallic atoms of Groups 14 to 16 to which a substituent may be bonded (preferred examples thereof include ═O, ═S, ═NR′, and ═C(R′)R′ (in which R′ represents a substituent)),

Ax represents an organic group having 2 to 30 carbon atoms and having at least one aromatic ring selected from the group consisting of an aromatic hydrocarbon ring and an aromatic heterocyclic ring, and preferred examples thereof include an aromatic hydrocarbon ring group; an aromatic heterocyclic group; an alkyl group having 3 to 20 carbon atoms and having at least one aromatic ring selected from the group consisting of an aromatic hydrocarbon ring and an aromatic heterocyclic ring; and an alkenyl group having 3 to 20 carbon atoms and having at least one aromatic ring selected from the group consisting of an aromatic hydrocarbon ring and an aromatic heterocyclic ring,

Ay represents a hydrogen atom, an alkyl group having 1 to 6 carbon atoms, which may have a substituent, or an organic group having 2 to 30 carbon atoms, which has at least one aromatic ring selected from the group consisting of an aromatic hydrocarbon ring and an aromatic heterocyclic ring, and suitable aspects of this organic group are the same as the suitable aspects of the organic group of Ax,

the aromatic rings in each of Ax and Ay may each have a substituent, and Ax and Ay may be bonded to each other to form a ring, and

Q₂ represents a hydrogen atom or an alkyl group having 1 to 6 carbon atoms, which may have a substituent.

Moreover, examples of the substituent include a halogen atom, an alkyl group, a halogenated alkyl group, an alkenyl group, an aryl group, a cyano group, an amino group, a nitro group, a nitroso group, a carboxyl group, an alkylsulfinyl group having 1 to 6 carbon atoms, an alkylsulfonyl group having 1 to 6 carbon atoms, a fluoroalkyl group having 1 to 6 carbon atoms, an alkoxy group having 1 to 6 carbon atoms, an alkylsulfanyl group having 1 to 6 carbon atoms, an N-alkylamino group having 1 to 6 carbon atoms, an N,N-dialkylamino group having 2 to 12 carbon atoms, an N-alkylsulfamoyl group having 1 to 6 carbon atoms, an N,N-dialkylsulfamoyl group having 2 to 12 carbon atoms, or a combination thereof.

For the definition and the preferred range of each substituent of the liquid crystal compound represented by General Formula (II), reference can be made to the description on D¹, D², G¹, G², L¹, L², R⁴, R⁵, R⁶, R⁷, X¹, Y¹, Q¹, and Q² for the compound (A) described in JP2012-021068A with regard to D₁, D₂, G₁, G₂, L₁, L₂, R¹, R², R³, R⁴, Q₁, Y₁, Z₁, and Z₂, respectively; reference can be made to the description on A₁, A₂, and X for the compound represented by General Formula (I) described in JP2008-107767A with regard to A₁, A₂, and X, respectively; and reference can be made to the description on Ax, Ay, and Q¹ for the compound represented by General Formula (I) described in WO2013/018526A with regard to Ax, Ay, and Q₂, respectively. Reference can be made to the description on Q¹ for the compound (A) described in JP2012-021068A with regard to Z₃.

In particular, the organic groups represented by L₁ and L₂ are each particularly preferably a group represented by -D₃-G₃-Sp-P₃.

D₃ has the same meaning as D₁.

G₃ represents a single bond, a divalent aromatic or heterocyclic group having 6 to 12 carbon atoms, or a divalent alicyclic hydrocarbon group having 5 to 8 carbon atoms, and the methylene group included in the alicyclic hydrocarbon group may be substituted with —O—, —S—, or —NR⁷—, in which R⁷ represents a hydrogen atom or an alkyl group having 1 to 6 carbon atoms.

Sp represents a single bond, or a spacer group represented by —(CH₂)ₙ—, —(CH₂)ₙ—O—, —(CH₂—O—)ₙ—, —(CH₂CH₂—O—)ₘ, —O—(CH₂)ₙ—, —O—(CH₂)ₙ—O—, —O—(CH₂—O—)ₙ—, —O—(CH₂CH₂—O—)ₘ, —C(═O)—O—(CH₂)ₙ—, —C(═O)—O—(CH₂)ₙ—O—, —C(═O)—O—(CH₂—O—)ₙ—, —C(═O)—O—(CH₂CH₂—O—)ₘ, —C(═O)—N(R⁸)—(CH₂)ₙ—, —C(═O)—N(R⁸)—(CH₂)—O—, —C(═O)—N(R⁸)—(CH₂—O—)ₙ—, —C(═O)—N(R⁸)—(CH₂CH₂—O—)ₘ, —(CH₂)ₙ—O(C═O)—(CH₂)ₙ—C(═O)O—(CH₂)ₙ—. Here, n represents an integer of 2 to 12, m represents an integer of 2 to 6, and R⁸ represents a hydrogen atom or an alkyl group having 1 to 6 carbon atoms. Further, the hydrogen atom of —CH₂— in each of the above groups may be substituted with a methyl group.

P₃ represents a polymerizable group.

The polymerizable group is not particularly limited, but is preferably a polymerizable group capable of radically polymerizable or cationically polymerizable group.

A generally known radically polymerizable group can be used as the radically polymerizable group, and suitable examples thereof include an acryloyl group and a methacryloyl group. In this case, it is known that the acryloyl group generally has a high polymerization rate, and from the viewpoint of improvement of productivity, the acryloyl group is preferable but the methacryloyl group can also be used in the same manner as the polymerizable group of a high birefringence liquid crystal.

A generally known cationically polymerizable group can be used as the cationically polymerizable group, and specific examples thereof include an alicyclic ether group, a cyclic acetal group, a cyclic lactone group, a cyclic thioether group, a spiroorthoester group, and a vinyloxy group. Among those, the alicyclic ether group or the vinyloxy group is preferable, and the epoxy group, the oxetanyl group, or the vinyloxy group is particularly preferable.

Particularly preferred examples of the polymerizable group include the following groups.

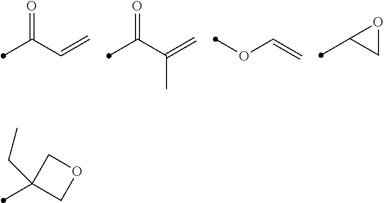

Moreover, in the present specification, the “alkyl group” may be linear, branched, or cyclic, and examples thereof include a methyl group, an ethyl group, an n-propyl group, an isopropyl group, an n-butyl group, an isobutyl group, a sec-butyl group, a tert-butyl group, an n-pentyl group, an isopentyl group, a neopentyl group, a 1,1-dimethylpropyl group, an n-hexyl group, an isohexyl group, a cyclopropyl group, a cyclobutyl group, a cyclopentyl group, and a cyclohexyl group.

Preferred examples of the liquid crystal compound represented by General Formula (II) are shown below, but are not limited to these liquid crystal compounds.

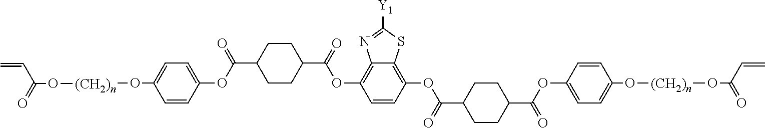

| No | Y1 | n | No | Y1 | n |
|---|---|---|---|---|---|
| II-1-1 | 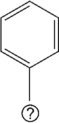 | 6 | II-1-9 | 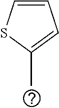 | 6 |
| II-1-2 | 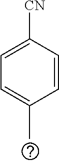 | 6 | II-1-10 | 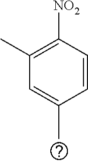 | 6 |
| II-1-3 | 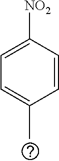 | 6 | II-1-11 | 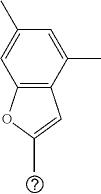 | 6 |
| II-1-4 | 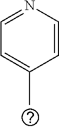 | 6 | II-1-12 | 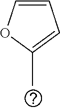 | 6 |
| II-1-5 | 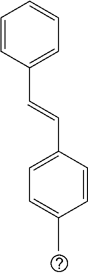 | 6 | II-1-13 | 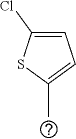 | 6 |
| II-1-6 | 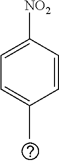 | 11 | II-1-14 | 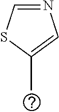 | 6 |
| II-1-7 | 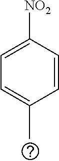 | 8 | II-1-15 | 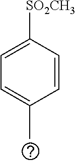 | 6 |
| II-1-8 | 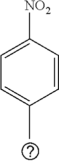 | 4 | | | |

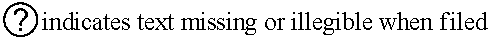

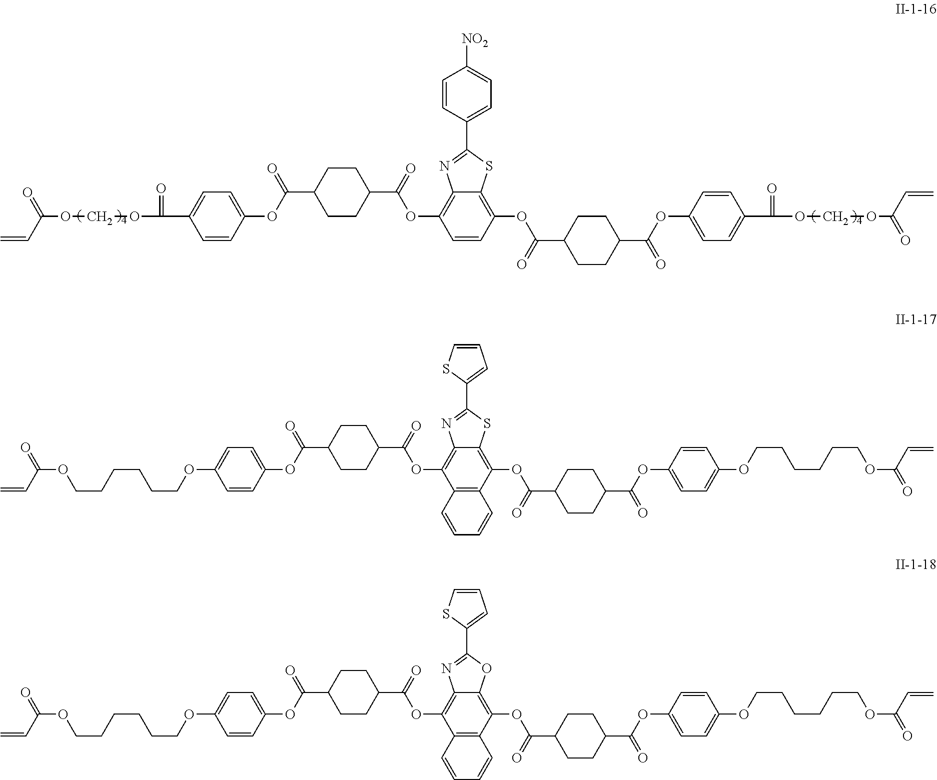

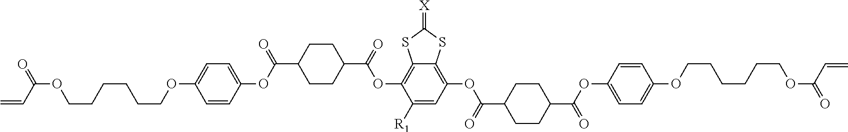

| No | X | R1 | No | X | R1 |
|---|---|---|---|---|---|
| II-2-1 | 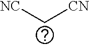 | H | II-2-5 | 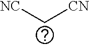 | CH₃ |
| II-2-2 | 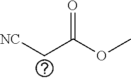 | H | II-2-6 | 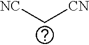 | 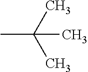 |
| II-2-3 | 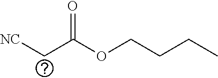 | H | II-2-7 | S | H |
| II-2-4 | 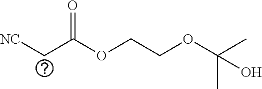 | H | | | |

Incidentally, in the formulae, “*” represents a bonding position.

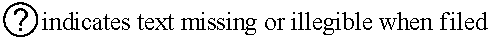

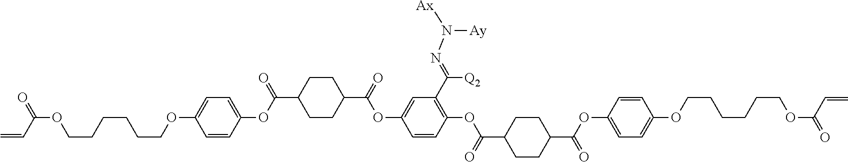

| No | Ax | Ay | Q2 |
|---|---|---|---|
| II-3-1 | 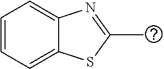 | H | H |
| II-3-2 | 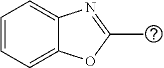 | H | H |
| II-3-3 | 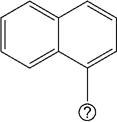 | H | H |
| II-3-4 | Ph | Ph | H |
| II-3-5 | 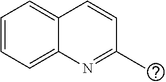 | H | H |
| II-3-6 | 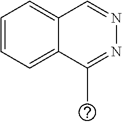 | H | H |
| II-3-7 | 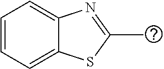 | CH₃ | H |
| II-3-8 | 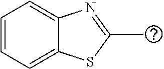 | CH₄H₉ | H |
| II-3-9 | 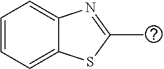 | C₆H₁₃ | H |
| II-3-10 | 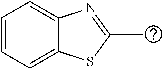 | 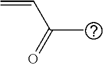 | H |
| II-3-11 | 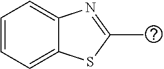 | 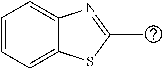 | H |
| II-3-12 | 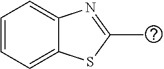 | CH₃CN | H |
| II-3-13 | 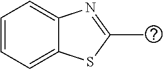 | 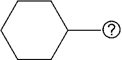 | H |
| II-3-14 | 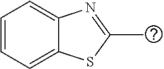 | 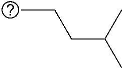 | H |
| II-3-15 | 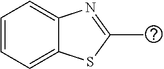 | CH₂CH₂OH | H |
| II-3-16 | 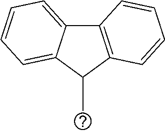 | H | H |
| II-3-17 | 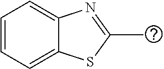 | CH₂CF₃ | H |
| II-3-18 | 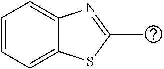 | H | CH₃ |
| II-3-19 | 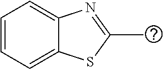 | 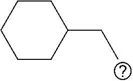 | H |
| II-3-20 | 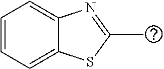 | 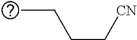 | H |
| II-3-21 | 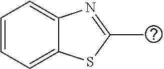 | 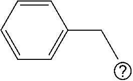 | H |
| II-3-22 | 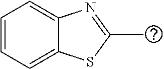 | 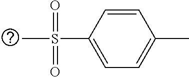 | H |
| II-3-23 | 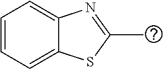 | 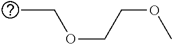 | H |
| II-3-24 | 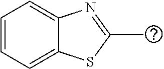 | 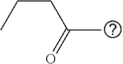 | H |
| II-3-25 | 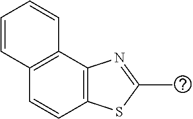 | C₆H₁₃ | H |

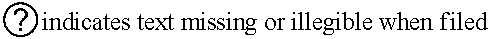

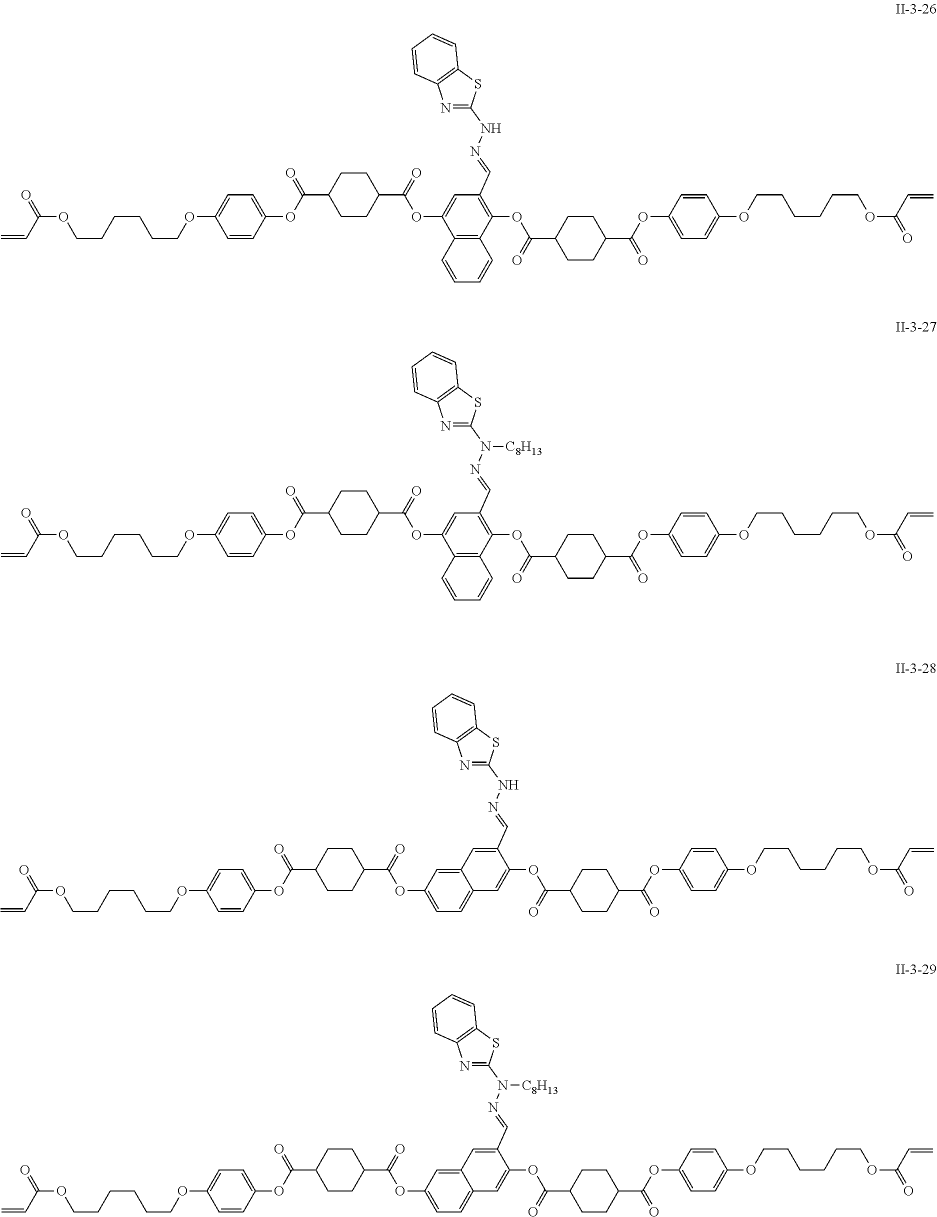

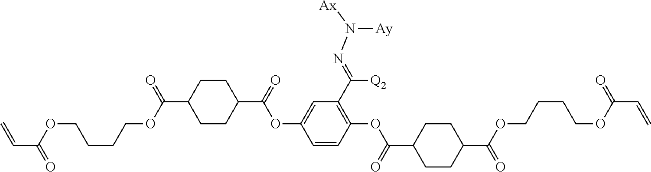

| No | Ax | Ay | Q2 |
|---|---|---|---|
| II-3-30 | 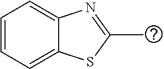 | H | H |
| II-3-31 | 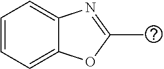 | H | H |
| II-3-32 | 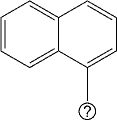 | H | H |
| II-3-33 | Ph | Ph | H |
| II-3-34 | 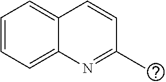 | H | H |
| II-3-35 | 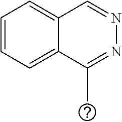 | H | H |
| II-3-36 | 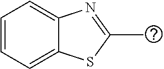 | CH₃ | H |
| II-3-37 | 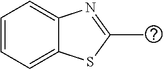 | CH₄H₉ | H |
| II-3-38 | 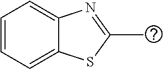 | C₆H₁₃ | H |
| II-3-39 | 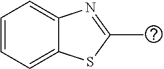 | 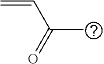 | H |
| II-3-40 | 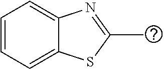 | 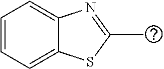 | H |
| II-3-41 | 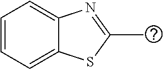 | CH₂CN | H |
| II-3-42 | 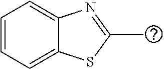 | 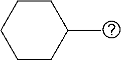 | H |
| II-3-43 | 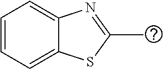 | 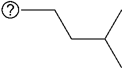 | H |
| II-3-44 | 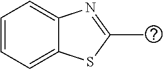 | CH₂CH₂OH | H |
| II-3-45 | 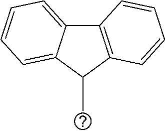 | H | H |
| II-3-46 | 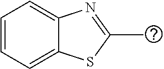 | CH₂CF₃ | H |
| II-3-47 | 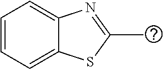 | H | CH₃ |
| II-3-48 | 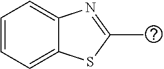 | 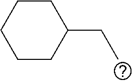 | H |
| II-3-49 | 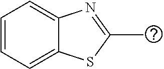 | 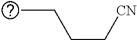 | H |
| II-3-50 | 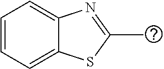 | 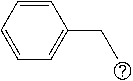 | H |
| II-3-51 | 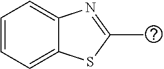 | 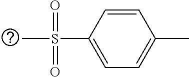 | H |
| II-3-52 | 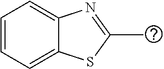 | 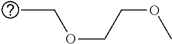 | H |
| II-3-53 | 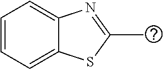 | 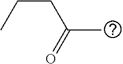 | H |
| II-3-54 | 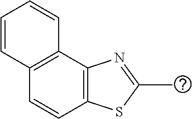 | C₆H₁₃ | H |

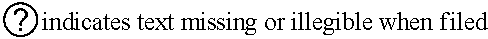

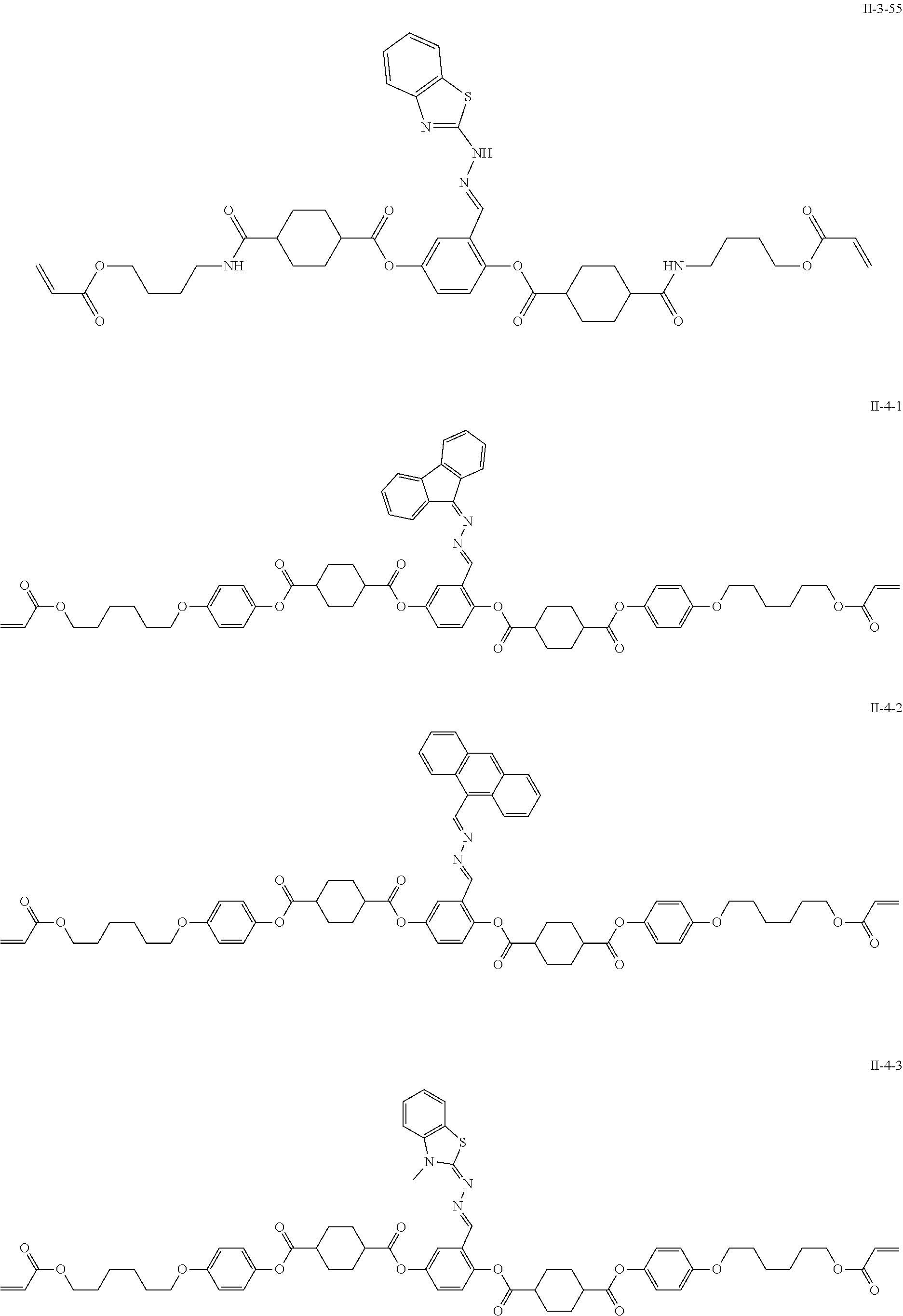

In a case where the liquid crystal compound represented by General Formula (II) is used, a content of the liquid crystal compound represented by General Formula (II) in the specific liquid crystal compound is preferably 60% to 100% by mass, more preferably 70% to 100% by mass, and still more preferably 70% to 90% by mass. By setting the content to 70% by mass or more, the reciprocal wavelength dispersion is more excellent. A plurality of these liquid crystal compounds may be used in combination.

(Polymerizable Rod-Shaped Compound)

In addition to the polymerizable liquid crystal compound having the reciprocal wavelength dispersion described above, a polymerizable rod-shaped compound can be added to the polymerizable composition. This polymerizable rod-like compound may or may not have liquid crystallinity. By the addition of the polymerizable rod-like compound, it is possible to improve the phase transition temperature and the alignment of the polymerizable composition, and the alignment stability at the time of fixing the alignment by polymerization.

Since it is mixed with the specific liquid crystal compound and handled as the polymerizable composition, any compound which has high compatibility with the specific liquid crystal compound can be preferably used. In particular, those having the structure of Formula (I) described in JP2015-163596A can be preferably used.

The addition amount is preferably 0% to 30%, and more preferably 0% to 20%, with respect to the above-mentioned liquid crystal compound having reciprocal wavelength dispersion.

(Polymerization Initiator)

The polymerizable liquid crystal composition forming the optically anisotropic layer can include a polymerization initiator.

The polymerization initiator to be used is preferably a photopolymerization initiator capable of initiating a polymerization reaction upon irradiation with ultraviolet rays.

Examples of the photopolymerization initiator include α-carbonyl compounds (described in each of the specifications of U.S. Pat. Nos. 2,367,661A and 2,367,670A), acyloin ethers (described in U.S. Pat. No. 2,448,828A), α-hydrocarbon-substituted aromatic acyloin compounds (described in U.S. Pat. No. 2,722,512A), multinuclear quinone compounds (as described in each of the specifications of U.S. Pat. Nos. 3,046,127A and 2,951,758A), combinations of a triarylimidazole dimer and a p-aminophenyl ketone (as described in U.S. Pat. No. 3,549,367A), acridine and phenazine compounds (described in JP1985-105667A (JP-S60-105667A) and U.S. Pat. No. 4,239,850A), oxadiazole compounds (described in U.S. Pat. No. 4,212,970A), and acyl phosphine oxide compounds (described in JP1988-040799B (JP-S63-040799B), JP1993-029234B (JP-H05-029234B), JP1998-095788A (JP-H10-095788A), and JP1998-029997A (JP-H10-029997A)).

In the present invention, for a reason that the durability of the optically anisotropic layer is better, the polymerization initiator is preferably an oxime-type polymerization initiator (described in the specification of U.S. Pat. No. 5,496,482A), and specifically, more preferably a polymerization initiator represented by Formula (III).

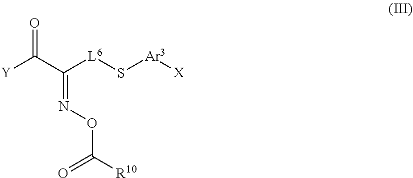

Here, in Formula (III), X represents a hydrogen atom or a halogen atom, and Y represents a monovalent organic group.

In addition, Ar³ represents a divalent aromatic group, L⁶ represents a divalent organic group having 1 to 12 carbon atoms, and R¹⁰ represents an alkyl group having 1 to 12 carbon atoms.

In Formula (III), examples of the halogen atom represented by X include a fluorine atom, a chlorine atom, a bromine atom, and an iodine atom, and among these, the chlorine atom is preferable.

Furthermore, in Formula (III), examples of the divalent aromatic group represented by Ar³ include a divalent group having at least one aromatic ring selected from the group consisting of an aromatic hydrocarbon ring and an aromatic heterocyclic ring exemplified as Ar² in Formula (II).

Incidentally, in Formula (III), examples of the divalent organic group having 1 to 12 carbon atoms represented by L⁶ include a linear or branched alkylene group having 1 to 12 carbon atoms, and specific suitable examples thereof include a methylene group, an ethylene group, and a propylene group.

Moreover, in Formula (III), specific suitable examples of the alkyl group having 1 to 12 carbon atoms represented by R¹⁰ include a methyl group, an ethyl group, and a propyl group.

In addition, in Formula (III), examples of the monovalent organic group represented by Y include a functional group including a benzophenone skeleton ((C₆H₅)₂CO). Specifically, as in the groups represented by Formula (2a) and Formula (2b), a functional group including a benzophenone skeleton in which a benzene ring at a terminal is unsubstituted or mono-substituted is preferable.

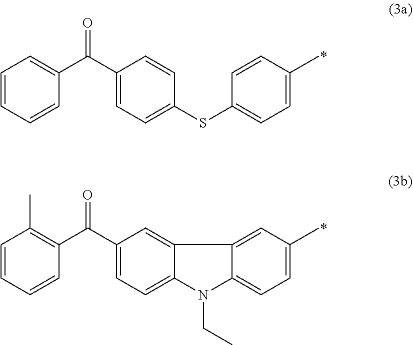 [SMILES: Cc1ccc(Sc2ccc(C(=O)c3ccccc3)cc2)cc1 ; CCn1c2ccc(C)cc2c2cc(C(=O)c3ccccc3C)ccc21]

Here, in Formula (3a) and Formula (3b), * represents a bonding position, and that is, a bonding position to the carbon atom of the carbonyl group in Formula (III).

Examples of the oxime-type polymerization initiator represented by Formula (III) include a compound represented by Formula S-1 and a compound represented by Formula S-2.

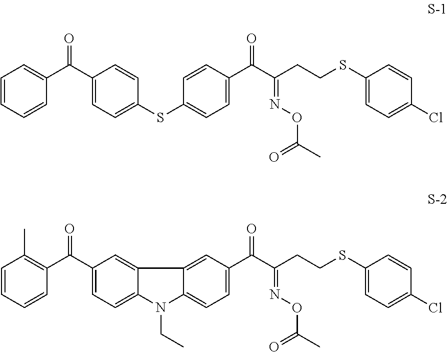 [SMILES: CC(=O)O/N=C(\CCSc1ccc(Cl)cc1)C(=O)c1ccc(Sc2ccc(C(=O)c3ccccc3)cc2)cc1 ; CCn1c2ccc(C(=O)/C(CCSc3ccc(Cl)cc3)=N/OC(C)=O)cc2c2cc(C(=O)c3ccccc3C)ccc21]

In the present invention, a content of the polymerization initiator is not particularly limited, but the content of the polymerization initiator is preferably 0.5 to 10 parts by mass, and more preferably 1 to 5 parts by mass, with respect to 100 parts by mass of the specific liquid crystal compound contained in the polymerizable liquid crystal composition of the present invention.

(Alignment Control Agent)

The polymerizable liquid crystal composition can contain an alignment control agent, as desired. As the alignment control agent, for example, a low-molecular-weight alignment control agent or a high-molecular-weight alignment control agent can be used. With regard to the low-molecular-weight alignment control agent, reference can be made to the description in, for example, paragraphs 0009 to 0083 of JP2002-020363A, paragraphs 0111 to 0120 of JP2006-106662A, and paragraphs 0021 to 0029 of JP2012-211306A, the contents of which are incorporated herein by reference. In addition, with regard to the high-molecular-weight alignment control agent, reference can be made to the description in, for example, paragraphs 0021 to 0057 of JP2004-198511A and paragraphs 0121 to 0167 of JP2006-106662A, the contents of which are incorporated herein by reference.

The amount of the alignment control agent to be used is preferably 0.01% to 10% by mass, and more preferably 0.05% to 5% by mass of the solid content of the liquid crystal composition in the polymerizable liquid crystal composition. By using the alignment control agent, for example, the liquid crystal compound can be in a homogeneous alignment state in which the liquid crystal compound is aligned in parallel with the surface of the layer.

(Other Polymerizable Compounds)

The polymerizable liquid crystal composition may contain a polymerizable compound other than the specific liquid crystal compound.

Here, the polymerizable group contained in the polymerizable compound is not particularly limited, and examples thereof include a (meth)acryloyl group, a vinyl group, a styryl group, and an allyl group. Among those, the (meth)acryloyl group is preferably contained.

In the present invention, a polymerizable compound having two or more polymerizable groups is preferable, and a polymerizable compound having 2 to 6 polymerizable groups is preferable for reasons of improvement in durability of the phase difference film, and the like.

Other examples of such polymerizable compounds include the compounds represented by Formulae (M1), (M2), and (M3) described in paragraphs [0030] to [0033] of JP2014-077068A, and more specifically, the specific examples described in paragraphs [0046]to [0055] of the same publication.

The polymerizable compounds may be used alone or in combination of two or more.

In the present invention, in a case where the polymerizable compound is contained, a content thereof is not particularly limited, but it is preferably 1 to 40 parts by mass, and more preferably 5 to 30 parts by mass, with respect to 100 parts by mass of a total amount of the specific liquid crystal compound and the polymerizable compound.

(Solvent)

It is preferable that the polymerizable liquid crystal composition contains a solvent from the viewpoints of workability for forming a phase difference film, and the like.

Specific examples of the organic solvent include ketones (for example, acetone, 2-butanone, methyl ethyl ketone, methyl isobutyl ketone, cyclohexanone, and cyclopentanone), ethers (for example, dioxane and tetrahydrofuran), aliphatic hydrocarbons (for example, hexane), alicyclic hydrocarbons (for example, cyclohexane), aromatic hydrocarbons (for example, toluene, xylene, and trimethylbenzene), halogenated carbons (for example, dichloromethane, dichloroethane, dichlorobenzene, and chlorotoluene), esters (for example, methyl acetate, ethyl acetate, and butyl acetate), water, alcohols (for example, ethanol, isopropanol, butanol, and cyclohexanol), cellosolves (for example, methyl cellosolve and ethyl cellosolve), cellosolve acetates, sulfoxides (for example, dimethyl sulfoxide), and amides (for example, dimethylformamide and dimethylacetamide), and these may be used singly or in combination of two or more kinds thereof.

(Other Components)

The polymerizable liquid crystal composition may contain other components other than the above components, and examples thereof include a liquid crystal compound other than the above compound, a leveling agent, a surfactant, an alignment aid, a plasticizer, a crosslinking agent, a moisture-heat resistance improver, a sensitizer, an ultraviolet absorber, a dye, and a radical quencher.

(Optical Characteristics and Alignment State of Optically Anisotropic Layer)

The optically anisotropic layer in the long phase difference film of the embodiment of the present invention can have various optical characteristics according to the purpose. These optical characteristics can be obtained by controlling the alignment state and the thickness of the polymerizable liquid crystal composition as described above. In one aspect of the present invention, a λ/4 plate that is a positive A-plate can be used. In addition, in another aspect of the present invention, a positive C-plate can be used.

(Positive A-Plate)

The optically anisotropic layer included in the phase difference film of the embodiment of the present invention can be a positive A-plate. A positive A-plate can be obtained by using a rod-shaped polymerizable liquid crystal compound and subjecting the compound to horizontal alignment (homogeneous alignment) in the polymerizable composition described above.

Moreover, in the present specification, the positive A-plate is defined as follows. The positive A-plate satisfies a relationship of Formula (A1) in a case where a refractive index in the slow axis direction in a film plane (in a direction such that the in-plane refractive index is maximum) is defined as nx, a refractive index in the in-plane direction orthogonal to the in-plane slow axis is defined as ny, and a thickness-direction refractive index is defined as nz. In addition, the Rth of the positive A-plate exhibits a positive value.

nx>ny≈nz Formula (A1)

Furthermore, the symbol, “≈”, encompasses not only a case where the both are completely the same as each other but also a case where the both are substantially the same as each other. An expression, “being substantially the same”, for example, “ny≈nz” also covers a case where (ny−nz)×d (in which d is a thickness of the film) is −10 nm to 10 nm, and preferably −5 nm to 5 nm.

With regard to details of a method for manufacturing the positive A-plate, reference can be made to, for example, the description in JP2008-225281A, JP2008-026730A, and the like.

(λ/4 Plate)

The optically anisotropic layer included in the phase difference film of the embodiment of the present invention preferably has the characteristics of a λ/4 plate. The λ/4 plate refers to a phase difference plate (phase difference film) in which an in-plane retardation Re(λ) at a specific wavelength λ nm satisfies Re(λ)=λ/4 or close to the same.

This formula may be achieved at any wavelength in the visible region (for example, λ=550 nm), and the in-plane retardation Re(550) at a wavelength of 550 nm preferably satisfies a relationship of 100 nm≤Re(550)≤160 nm, and more preferably satisfies a relationship of 110 nm≤Re(550)≤150 nm.

In a case of using the above-described polymerizable liquid crystal composition having reciprocal wavelength dispersion, the phase difference becomes close to Re(λ)=λ/4 even at wavelengths of 450 nm and 650 nm, and an optically anisotropic layer acting as a λ/4 plate in a wide wavelength range can be obtained, as compared with a case of using a liquid crystal composition with forward dispersion. Such a broadband λ/4 plate contributes to, for example, formation of a broadband circularly polarizing plate suitable for a circularly polarizing plate (the incident light from the linearly polarizing plate side is emitted as circularly polarized light from the λ/4 plate side) obtained by arranging and laminating the slow axis of the optically anisotropic layer at 30° to 50°, and preferably 45° with respect to the transmission axis of the linearly polarizing plate, and thus, the broadband λ/4 plate can be suitably used as, for example, a film for preventing internal reflection in an image display device as described later.

In a case where the long phase difference film is used as the broadband circularly polarizing plate as above, it is preferable that the in-plane slow axis of the optically anisotropic layer forms an angle of 30° to 500 with respect to the longitudinal direction of the long support.

(Positive C-Plate)

The optically anisotropic layer included in the phase difference film of the embodiment of the present invention can be a positive C-plate. A positive C-plate can be obtained by using a rod-shaped polymerizable liquid crystal compound and subjecting the compound to vertically alignment (homeotropical alignment) in the above-described polymerizable composition.

Moreover, in the present specification, the positive C-plate is defined as follows. The positive C-plate satisfies a relationship of (C1) in a case where a refractive index in one direction in the film plane is nx, a refractive index in the direction orthogonal to the direction of nx is ny, and a refractive index in the thickness direction is nz. In addition, in the positive C-plate, the Rth exhibits a negative value.

nx≈ny<nz Formula (C1)

Furthermore, the symbol, “≈”, encompasses not only a case where the both are completely the same as each other but also a case where the both are substantially the same as each other. An expression, “being substantially the same”, for example, “nx≈ny” also covers a case where (nx−ny)×d (in which d is a thickness of the film) is −10 nm to 10 nm, and preferably −5 nm to 5 nm.

(Alignment State of Optical Anisotropy)

In the optically anisotropic layer contained in the long phase difference film of the embodiment of the present invention, a degree S0 of alignment order of optical anisotropy of the polymerizable liquid crystal compound at a maximum absorption wavelength in the range of 320 nm to 400 nm, as measured using the solution (a), can be −0.50<S0<−0.15. Here, the solution (a) is a solution obtained by dissolving a polymerizable liquid crystal compound having reciprocal wavelength dispersion to be used in chloroform so that the solution has a concentration of 10⁻⁴ mol/l.

The degree S (λ) of alignment order of the optically anisotropic layer is a value represented by Equation (S1).

S(λ)=(Ap−Av)/(Ap+2Av) Equation (S1)

[In Equation (1), Ap represents an absorbance for light polarized in the direction parallel to the alignment direction of the polymerizable liquid crystal compound having reciprocal wavelength dispersion included in the optically anisotropic layer (for example, the in-plane slow axis direction in a case of the positive A-plate). Av represents an absorbance for light polarized in the direction orthogonal to the alignment direction of the polymerizable liquid crystal compound included in the optical film.]

The degree S (λ) of alignment order of the optical film can be determined by measuring a polarization absorption at that wavelength, in which λ is a maximum absorption peak value at 320 nm to 400 nm of the polymerizable liquid crystal compound having reciprocal wavelength dispersion. The degree S0 of alignment order can satisfy −0.50<S0<−0.15 as described above, and preferably satisfies −0.48<S0<−0.20. Within this range, it is possible to obtain an optically anisotropic layer having excellent alignment, refractive index anisotropy, and reciprocal wavelength dispersion while suppressing crystallization of the liquid crystal compound.

In a state immediately before the curing treatment of the optically anisotropic layer of the long phase difference film of the embodiment of the present invention (also referred to as a “liquid crystal layer (uncured)”), the liquid crystal compound may be in a state exhibiting a nematic phase or a smectic phase. In order to increase the above-mentioned degree S0 of alignment order and obtain the effect, it is preferable that the compound exhibits a smectic phase. Such the state can be controlled to a temperature with the thermotropic liquid crystal as described later, the polymerizable liquid crystalline composition used in the present invention is preferably a polymerizable liquid crystal composition having a smectic phase, and a phase transition temperature from the nematic phase to the smectic phase can be 20° C. to 120° C., is preferably 60° C. or higher, and more preferably 80° C. or higher. Within this range, the degree of alignment order can be controlled in a temperature range that can be handled by a common film forming apparatus, the alignment hardly collapses even under the heat-curing conditions which will be described below, and it is possible to achieve both the durability of the optically anisotropic layer and the degree of alignment order of the liquid crystal compound included in the composition.

In a case where the optically anisotropic layer of the present invention is the positive C-plate, a thickness-direction phase difference change ΔRth of the following equation can be used instead of the in-plane phase difference change ΔRe.

ΔRth=|Rtha(550)−Rthb(550)|÷|Rtha(550)|

[Here, Rtha(550) represents a thickness-direction phase difference of the section of the phase difference film before heating at a measurement wavelength of 550 nm, and Rthb(550) represents a thickness-direction phase difference value of the section of the phase difference film after a treatment under a heating condition of 85° C. and 500 hours.]In the embodiment in which the optically anisotropic layer of the present invention is the positive C-plate, ΔRth can be 0.94 to 1.02, and is more preferably 0.96 to 1.01.

Such a phase difference film can be achieved by satisfying both a high degree of alignment order and a high polymerization reaction rate of the polymerizable liquid crystal composition, and can be specifically realized by a method for producing a phase difference film which will be described below.

### [Method for Producing Phase Difference Film]

A method for forming the long phase difference film of the embodiment of the present invention is not particularly limited, and a known method can be used.

Typically, it is possible to produce a phase difference film including a cured coating film (optically anisotropic layer) by continuously applying the polymerizable liquid crystal composition onto a long support to form a long coating film, and subjecting the obtained coating film to a curing treatment (irradiation with active energy rays (light irradiation treatment) and/or heat treatment). In addition, the above-mentioned alignment layer, alignment treatment, and the like may be used, as desired.

Here, a preferred method for producing the long phase difference film of the embodiment of the present invention is a method for producing a long phase difference film, including

an applying step of forming a coating film by applying a polymerizable liquid crystal composition including a polymerizable liquid crystal compound having reciprocal wavelength dispersion onto one surface of a long support formed of a resin film while transporting the long support in the longitudinal direction; and

a curing step of curing the coating film to form an optically anisotropic layer,

in which the long support has a thickness of 10 μm to 50 m, a width-direction elastic modulus of 4.3 GPa to 6.0 GPa, and a width-direction coefficient of linear thermal expansion of 10 ppm/° C. to 35 ppm/° C., and

in the curing step, the coating film is cured while heating the coating film to a temperature from 80° C. to 140° C.

Moreover, in the curing step, the coating film is preferably cured by irradiation with active energy rays (light irradiation). The active energy rays are preferably ultraviolet rays.

In addition, it is preferable that irradiation with active energy rays is performed at a position where the long support is in contact with a backup roll.

Furthermore, it is preferable that the long phase difference film of the embodiment of the present invention is subjected to a so-called roll-to-roll (R to R) method in which each step is performed in a transport path while the long support is transported in the longitudinal direction.

Application of the polymerizable liquid crystal composition can be carried out by a known method (for example, a wire bar coating method, an extrusion coating method, a direct gravure coating method, a reverse gravure coating method, and a die coating method). After the application, the solvent included in the composition can be removed by appropriately heating or reducing the pressure as desired. Drying may be performed at the same time as the alignment treatment described below.

An alignment treatment to which the coating layer of the polymerizable liquid crystal composition is subjected to can be performed by heating. In a case of a thermotropic liquid crystal compound, a liquid crystal phase formed by the alignment treatment can be generally transferred by a change in the temperature.

In a case where the polymerizable liquid crystal composition to be used expresses a thermotropic smectic phase, the temperature range in which the nematic phase is expressed is generally higher than the temperature range in which a smectic phase is expressed. Therefore, it is possible to transfer the specific liquid crystal compound from the nematic phase to the smectic phase by heating the specific liquid crystal compound to a temperature range in which the nematic phase is expressed, and then lowering the heating temperature to a temperature range in which the specific liquid crystal compound expresses the smectic phase. In a case where it is desired to form a nematic layer, and in a case where the polymerizable liquid crystalline composition does not have a smectic phase, the composition can once be heated to no lower than a temperature at which the nematic phase is exhibited or a temperature at which a transition from a nematic phase to an isotropic layer is made, and then subjected to an alignment treatment by keeping the composition at a temperature at which the nematic phase is exhibited.

In a case where the polymerizable liquid crystal compound having reciprocal wavelength dispersion, used in the present invention is a rod-shaped liquid crystal, it is necessary to perform heating for a certain period of time until the specific liquid crystal compound forms a monodomain in a temperature range in which a nematic phase is expressed. The heating time (heating aging time) is preferably 10 seconds to 5 minutes, more preferably 10 seconds to 3 minutes, and most preferably 10 seconds to 2 minutes.

The curing treatment (irradiation with active energy rays (light irradiation treatment) and/or heat treatment) for the coating film which has been subjected to the alignment treatment as described above is referred to as a fixing treatment for fixing the alignment of the polymerizable liquid crystal compound.

The fixing treatment is preferably performed by irradiation with active energy rays (preferably ultraviolet rays), and the liquid crystal is fixed by polymerization of the specific liquid crystal compound. In this case, by elevating the temperature of the coating film, the polymerization reaction is accelerated, and thus, an optically anisotropic layer having excellent durability can be formed. As the heating condition, the range of 80° C. to 140° C. is preferable, and the range of 90° C. to 140° C. is more preferable. Within this range, the thermal decomposition of each material is suppressed while imparting excellent durability to the optically anisotropic layer, and thus, a high-quality long phase difference film can be produced.

In addition, the irradiation amount of the active energy rays may be appropriately set according to the type of the polymerizable liquid crystal compound, the type of the polymerization initiator, the type of the active energy rays, and the like. For example, In a case of irradiating ultraviolet rays as the active energy rays, the irradiation amount is preferably 100 to 500 mJ/cm².

However, as described in the beginning, high-temperature heating after the alignment treatment may destroy the alignment state of a liquid crystal thus formed, and there is a restriction that the treatment should be performed in an extremely short time from the start of heating to the curing treatment. Therefore, in the production of the long phase difference film of the embodiment of the present invention, the heating means and the curing treatment means are preferably performed continuously or substantially at the same time. Examples of the heating means include heating by elevating the temperature of the atmosphere, heating through a contact with a heat source, and heating through radiation with infrared rays or the like, but the heating through a contact with a heat roll or the like is preferable from the viewpoint that the temperature elevation rate of the coating film and the uniformity of heating are excellent. In a case where irradiation with active energy rays is used as the curing treatment means, a backup roll facing an irradiation device is preferably a heat roll (heating means). In addition, preheating is preferably performed before the heating through the effect treatment within a range that does not affect the alignment state.

A long phase difference film including the optically anisotropic layer in which the alignment of the polymerizable liquid crystal composition is fixed as described above can be subjected to a post-heating treatment and provision with a liner film or a surface protective film, as desired, and thus, can be formed into a wound body wound on a winding core. In a case of a long phase difference film having a total length exceeding 500 m, knurling can be provided at both ends of the film for the purpose of preventing the wound film from rubbing against each other. In a case where a long support having a high elastic modulus is used in the width direction described above, a gap between the films supported by the knurling is favorably maintained, the surface failure is suppressed, and the quality of the phase difference film can be maintained at a high level.

[Long Laminate]

The long laminate (long polarizing plate) of the embodiment of the present invention has the above-mentioned long phase difference film and a long linearly polarizing film. The description of the phase difference film is as described above and will not be repeated.

<Long Linearly Polarizing Film>

The long linearly polarizing film may be a so-called linear polarizer having a function of converting light into specific linearly polarized light. The polarizer is not particularly limited, but an absorption polarizer can be used.

A type of the polarizer is not particularly limited, a commonly used polarizer can be used, and for example, any of an iodine-based polarizer, a dye-based polarizer using a dichroic dye, a polyene-based polarizer, and a polarizer using a wire grid can be used. The iodine-based polarizer and the dye-based polarizer are generally manufactured by adsorbing iodine or a dichroic dye onto polyvinyl alcohol and stretching the resultant.

Furthermore, it is also preferable to use a coating type polarizer manufactured by coating or the like, using a thermotropic liquid crystalline dichroic dye (for example, the thermotropic liquid crystalline dichroic dye used for a light-absorbing anisotropic film described in JP2011-237513A) as the polarizer. By using the coating type polarizer, it is possible to further reduce the thickness of a polarizer obtained by stretching polyvinyl alcohol. Incidentally, even in a case where an external force such as bending is applied, a polarizing plate with a small change in optical characteristics can be provided.

A thickness of the polarizer is not particularly limited, but is preferably 1 μm to 40 μm, more preferably 2 μm to 30 μm, and still more preferably 3 μm to 20 μm in a case of a typical polyvinyl alcohol polarizer. With the above thickness, it is possible to reduce the thickness of a display device. In a case of the coating type polarizer, the thickness can be in the range of 0.5 μm to 3 μm.

By appropriately designing the optical characteristics of the phase difference film of the embodiment of the present invention, various high-performance polarizing plates can be obtained by laminating with a polarizer. For example, an ideal circularly polarizing plate can be obtained by setting the phase difference film of the embodiment of the present invention to a λ/4 plate and setting the slow axis to 45° or 135° with respect to the transmission axis of the polarizer. Further, by setting the in-plane phase difference Re of the phase difference film of the embodiment of the present invention to 100 to 150 nm and setting the slow axis thereof to be parallel or orthogonal to the transmission axis of the polarizer, the phase difference film can be used as an optical compensation layer of an IPS-mode liquid crystal display panel. In addition to this, polarizing plates with various optically anisotropic layers, circularly polarizing plates, or elliptically polarizing plates can be constituted by applying various optical designs to combine a polarizer and the phase difference film of the embodiment of the present invention.

The long laminate (long polarizing plate) is generally manufactured so that the longitudinal direction of the long phase difference film (long support) and the absorption axis of the long linearly polarizing film coincide with each other. That is, the width direction of the long phase difference film (long support) is in a relationship to be orthogonal to the absorption axis of the long linearly polarizing film. Therefore, in a case where the absorption axis of the linearly polarizing film is known from the polarizing plate (section) used for an image display device or the like, the width direction of the long support can be known.

<Other Layers>

(Polarizer Protective Film)

A polarizer protective film may be arranged on a surface of the polarizer. The polarizer protective film may be arranged only on one surface of the polarizer (on the surface opposite to the phase difference film side) or may be arranged on both surfaces of the polarizer.

The configuration of the polarizer protective film is not particularly limited, and may be, for example, a transparent support or a hard coat layer, or a laminate of the transparent support and the hard coat layer. Further, the support layer of the phase difference film of the embodiment of the present invention may also serve as a polarizer protective film.

As the hard coat layer, a known layer can be used, and for example, a layer obtained by polymerizing and curing polyfunctional monomers may be used. An antiglarc property or an antistatic property may be imparted to the hard coat layer, as desired.

In addition, a known transparent support can be used as the transparent support, and for example, as a material forming the transparent support, a cellulose-based polymer typified by triacetyl cellulose (hereinafter referred to as cellulose acylate), a thermoplastic norbornene-based resin (ZEONEX or ZEONOR manufactured by Nippon Zeon Co., Ltd., ARTON manufactured by JSR Corporation, and the like), an acrylic resin, or a polyester-based resin can be used.

A thickness of the polarizer protective film is not particularly limited, but is preferably 40 μm or less, and more preferably 25 μm or less since the thickness of the polarizing plate can be reduced. From the viewpoint of film handling, the thickness is preferably 5 μm or more, and more preferably 12 μm or more.

A pressure-sensitive adhesive layer or an adhesive layer may be provided between the respective layers to ensure adhesion between the respective layers. In order to combine functions of a touch panel and the like, a fine pattern of a transparent conductive layer or a metal layer may be provided in contact with any of the layers.

[Image Display Device]

A polarizing plate which is one type of the long laminate can be preferably used for an organic electroluminescent device (preferably an organic electroluminescent (EL) display device) or an image display device such as an LED display and a liquid crystal display device.

In this case, the long laminate may be cut out to a desired size (the size of the display area of the image display device) and used as a polarizing plate. Further, at the time of cutting out from the long laminate, cutting may be performed so that the longitudinal direction of the polarizing plate to be cut out and the longitudinal direction of the long laminate may coincide with each other; cutting may be performed so that the longitudinal direction of the polarizing plate to be cut out and the width direction of the long laminate may coincide with each other; or cutting may be performed so that the longitudinal direction of the polarizing plate to be cut out is oblique to the longitudinal direction of the long laminate.

<Liquid Crystal Display Device>

A liquid crystal display device is an example of the image display device, and has a polarizing plate cut out from the above-mentioned long laminate of the embodiment of the present invention and a liquid crystal cell.

In addition, in the present invention, it is preferable that the polarizing plate of the embodiment of the present invention is used as the polarizing plate on the front side, out of the polarizing plates provided on the both sides of the liquid crystal cell, and it is more preferable that the polarizing plate of the embodiment of the present invention is used as the polarizing plates on the front and rear sides. Further, it is preferable that the phase difference film included in the polarizing plate is arranged on the liquid crystal cell side.

That is, the phase difference film of the embodiment of the present invention can be suitably used as an optical compensation film.

Hereinafter, the liquid crystal cell constituting the liquid crystal display device will be described in detail.

(Liquid Crystal Cell)

A liquid crystal cell to be used for the liquid crystal display device is preferably in a vertical alignment (VA) mode, an optical compensated bend (OCB) mode, an in-place-switching (IPS) mode, or a twisted nematic (TN) mode, but the liquid crystal cell is not limited thereto.

In a TN-mode liquid crystal cell, rod-shaped liquid crystalline molecules are substantially horizontally aligned and are twist-aligned at 60° to 120° during no voltage application thereto. A TN-mode liquid crystal cell is most often used in a color TFT liquid crystal display device and described in numerous documents.

In a VA-mode liquid crystal cell, rod-shaped liquid crystalline molecules are substantially vertically aligned during no voltage application thereto. Examples of the VA-mode liquid crystal cell include (1) a VA-mode liquid crystal cell in the narrow sense of the word, in which rod-shaped liquid crystalline molecules are substantially vertically aligned during no voltage application thereto, but are substantially vertically aligned during voltage application thereto (described in JP1990-176625A (JP-H02-176625A)), (2) an MVA-mode liquid crystal cell in which the VA mode is multi-domained for viewing angle enlargement (described in SID97, Digest of Tech. Papers (preprint), 28 (1997) 845), (3) a liquid crystal cell in a mode (n-ASM mode) in which rod-shaped liquid crystal molecules are substantially vertically aligned during no voltage application thereto and are multi-domain-aligned during voltage application thereto (described in Seminar of Liquid Crystals of Japan, Papers (preprint), 58-59 (1998)), and (4) a survival-mode liquid crystal cell (announced in LCD International 98). In addition, the liquid crystal cell may be of any of a patterned vertical alignment (PVA) type, a photo-alignment type, and polymer-sustained alignment (PSA) type. Details of these modes are specifically described in JP2006-215326A and JP2008-538819A.

In an IPS-mode liquid crystal cell, rod-shaped liquid crystal molecules are aligned substantially parallel with respect to a substrate, and application of an electric field parallel to the substrate surface causes the liquid crystal molecules to respond planarly. The IPS mode displays black in a state where no electric field is applied and a pair of upper and lower polarizing plates have absorption axes which are orthogonal to each other. A method of improving the viewing angle by reducing light leakage during black display in an oblique direction using an optical compensation sheet (optical compensation film) is disclosed in JP1998-054982A (JP-H10-054982A), JP1999-202323A (JP-H11-202323A), JP1997-292522A (JP-H09-292522A), JP1999-133408A (JP-H11-133408A), JP1999-305217A (JP-H11-305217A), JP1998-307291 A (JP-H10-307291A), and the like.

<Organic EL Display Device>

As an organic EL display device which is an example of the organic electroluminescent device, for example, an aspect in which a circularly polarizing plate cut out from the long laminate of the embodiment of the present invention and an organic EL display panel are provided in this order from the visual recognition side is preferably mentioned. It is preferable that the phase difference film included in the circularly polarizing plate is arranged on the organic EL display panel side.

That is, the circularly polarizing plate including the phase difference film of the embodiment of the present invention is used as a so-called antireflection film that prevents light incident from the outside from being reflected by a panel electrode or the like and lowering the contrast of display light. Furthermore, the organic EL display panel is a display panel constituted with an organic EL device in which an organic light emitting layer (organic electroluminescent layer) is interposed between electrodes (between a cathode and an anode). The configuration of the organic EL display panel is not particularly limited but any known configurations are adopted.

[Transfer Film]

By producing the long phase difference film of the embodiment of the present invention so that peeling occurs at least one of between the support and the optically anisotropic layer, between the alignment layer and the optically anisotropic layer, or between the support and the alignment layer, and transferring a laminate including only an optically anisotropic layer or including the optically anisotropic layer and other layers other than a support to another support or an adherend such as a polarizing plate, it is possible to configure a high-performance polarizing plate or an image display device including the same. That is, in another aspect, the long phase difference film of the embodiment of the present invention can be used as a long transfer film using a temporary support as the support.

### EXAMPLES

Hereinafter, the present invention will be described in detail with reference to Examples.

[Manufacture of Cellulose Acylate Film 1]

(Manufacture of Core Layer Cellulose Acylate Dope)

The following composition was put into a mixing tank and stirred to dissolve the respective components to prepare a cellulose acetate solution used as a core layer cellulose acylate dope.

Core layer cellulose acylate dope

| | | |
|---|---|---|
| Cellulose acetate having a degree of acetyl | 100 | parts by mass |
| substitution of 2.88 | | |
| Polyester compound B describes in Examples of | 12 | parts by mass |
| JP2015-227955A | | |
| The following compound F | 2 | parts by mass |
| Methylene chloride (first solvent) | 436 | parts by mass |
| Methanol (second solvent) | 64 | parts by mass |

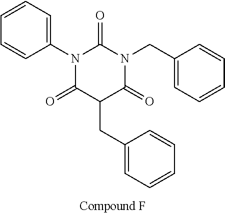 [SMILES: O=C1C(Cc2ccccc2)C(=O)N(c2ccccc2)C(=O)N1Cc1ccccc1]

(Manufacture of Outer Layer Cellulose Acylate Dope)

10 parts by mass of the following matting agent solution was added to 90 parts by mass of the above-mentioned core layer cellulose acylate dope to prepare a cellulose acetate solution used as an outer layer cellulose acylate dope.

Matting agent solution

| | |
|---|---|
| Silica particles with average particle size of 20 nm | 2 parts by mass |
| (AEROSIL R972, manufactured by Nippon Aerosil | |
| Co., Ltd.) | |
| Methylene chloride (first solvent) | 76 parts by mass |
| Methanol (second solvent) | 11 parts by mass |
| The core layer cellulose acylate dope | 1 part by mass |

(Formation of Cellulose Acylate Film 1)

The core layer cellulose acylate dope and the outer layer cellulose acylate dope were filtered through a filter paper having an average pore diameter of 34 μm and a sintered metal filter having an average pore diameter of 10 μm, and then three layers composed of the core layer cellulose acylate dope and the outer layer cellulose acylate dopes on both sides thereof were simultaneously cast from a casting port onto a metal band at 20° C. (band caster). Peeling was performed in a state of a solvent content of approximately 20% by mass, and the both ends of the film in the width direction were fixed with a tenter clip and dried while stretching the film at a stretching ratio of 1.1 times in the transverse direction. Thereafter, the film was further dried by transporting the film between rolls in a heat treatment device and wound up to manufacture a long cellulose acylate film 1 having a thickness of 40 μm. The core layer of the film had a thickness of 36 μm and the outer layers arranged on both sides of the core layer each had a thickness of 2 μm. The in-plane retardation of the obtained cellulose acylate film 1 was 0 nm. The width-direction elastic modulus, the width-direction elastic modulus at 140° C., and the width-direction coefficient of linear thermal expansion, each as measured in the evaluation direction which will be described later, were each as in Table 1.

(Formation of Cellulose Acylate Film 2)

A cellulose acylate film 2 was manufactured in the same manner as for the cellulose acylate film 1, except that the thickness was set to 20 μm (the thickness of the core layer was 15 μm and the thickness of the outer layers arranged on both sides of the core layer was 2.5 μm) in the formation of the cellulose acylate film 1. The width-direction elastic modulus, the width-direction elastic modulus at 140° C., and the width-direction coefficient of linear thermal expansion were as shown in Table 1.

(Cellulose Acylate Films 3 and 4)

As the cellulose acylate film 3, a commercially available long product of a cellulose acetate film (ZRD40SL, manufactured by FUJIFILM Corporation) was used. In addition, as the cellulose acylate film 4, a commercially available long product of a cellulose acetate film (ZRD60SL, manufactured by FUJIFILM Corporation) was used. The width-direction elastic modulus, the width-direction elastic modulus at 140° C., and the width-direction coefficient of linear thermal expansion were as shown in Table 1.

(Synthesis of Polymer A1 Having Photo-Alignment Group)

A flask equipped with a cooling pipe and a stirrer was charged with 1 part by mass of 2,2′-azobis(isobutyronitrile) as a polymerization initiator and 180 parts by mass of diethylene glycol methyl ethyl ether as a solvent. 100 parts by mass of 3,4-epoxycyclohexylmethyl methacrylate was added thereto and the atmosphere in the flask was replaced with nitrogen, followed by gentle stirring. The solution temperature was elevated to 80° C. and the temperature was maintained for 5 hours to obtain a polymer solution containing about 35% by weight of a polymethacrylate having an epoxy group. The weight-average molecular weight Mw of the obtained epoxy-containing polymethacrylate was 25,000.

Then, another reaction vessel was charged with 286 parts by mass of the solution containing the epoxy-containing polymethacrylate obtained above (100 parts by mass in terms of polymethacrylate), 120 parts by mass of a cinnamic acid derivative obtained by the method of Synthesis Example 1 of JP2015-026050A, 20 parts by mass of tetrabutylammonium bromide as a catalyst, and 150 parts by mass of propylene glycol monomethyl ether acetate as a diluting solvent, and the mixture was reacted under stirring in a nitrogen atmosphere at 90° C. for 12 hours. After the completion of the reaction, 100 parts by mass of propylene glycol monomethyl ether acetate was added to the reaction mixture to dilute the mixture, and the resultant was washed three times with water. The organic phase after washing with water was poured into a large excess of methanol to precipitate a polymer, and the recovered precipitate was vacuum-dried at 40° C. for 12 hours to obtain the following polymer A1 having a photo-alignment group.

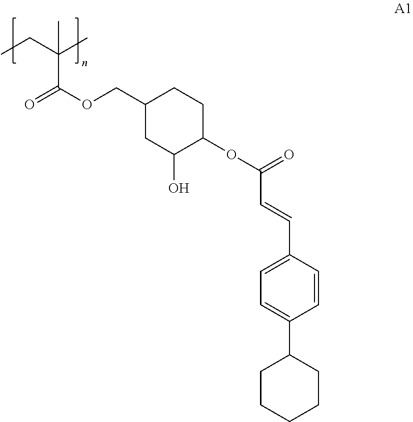

### Example 1

[Manufacture of Long Phase Difference Film]

The following composition 1 for a photo-alignment film was continuously applied to one surface of the manufactured cellulose acylate film 1 using a bar coater. After the application, the solvent was removed by drying in a heating zone at 120° C. for 1 minute to form a 0.3 nm-thick photoisomerizable composition layer. Subsequently, a long photo-alignment film was formed by irradiating polarized ultraviolet rays (10 mJ/cm², using an ultra-high-pressure mercury lamp) so that the polarization axis formed an angle of 45° in the longitudinal direction while winding around a mirror-treated backup roll.

Composition 1 for Optical Alignment Film

| | | |
|---|---|---|
| Polymer A1 having the photo-alignment group | 10 | parts by mass |
| NOMCORT TAB (manufactured by | 152 | parts by mass |
| Nisshin Oillio Co., Ltd.) | | |
| Polyfunctional epoxy compound (EPOLEAD | 12.2 | parts by mass |
| GT401, manufactured by Daicel Corporation) | | |
| Thermal acid generator (San-Aid SI-60, | 0.55 | parts by mass |
| manufactured by Sanshin Chemical | | |
| lndustry Co., Ltd.) | | |
| Butyl acetate | 300 | parts by mass |

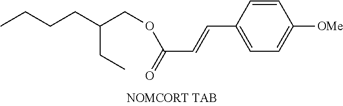 [SMILES: CCCCC(CC)COC(=O)/C=C/c1ccc(OC)cc1]

Subsequently, the following composition 1 for forming an optically anisotropic layer was applied by a die coater on the long photo-alignment film to form a liquid crystal layer (uncured). Thereafter, the temperature was kept at 120° C., the alignment was fixed by irradiation with ultraviolet rays (using an ultra-high-pressure mercury lamp) in a nitrogen atmosphere (oxygen concentration: 100 ppm) to form an optically anisotropic layer having a thickness of 2.3 μm, and the obtained film was wound around a winding core to manufacture a long phase difference film 1. The obtained phase difference film had an average in-plane retardation Re(550) of 140 nm, which satisfied Re(450)/Re(550)<1.0 and 1.0<Re(650)/Re(550), and the average slow axis direction was 45° with respect to the longitudinal direction. In addition, the wavelength dispersion (Re(450)/Re(550)) was measured by AxoScan and found to be 0.87.

Coating liquid (liquid crystal 1) for optically anisotropic layer

| | |
|---|---|
| The following liquid crystalline compound L-3 | 42.00 parts by mass |
| The following liquid crystalline compound L-4 | 42.00 parts by mass |
| The following polymerizable compound A-1 | 16.00 parts by mass |
| The following polymerization initiator S-1 (oxime | 0.50 parts by mass |
| type) | |
| Leveling agent (the following compound G-1) | 0.20 parts by mass |
| High Solve MTEM (manufactured by Toho | 2.00 parts by mass |
| Chemical Industry Co., Ltd.) | |
| NK Ester A-200 (manufactured by Shin-Nakamura | 1.00 part by mass |
| Chemical Co., Ltd.) | |
| Methyl ethyl ketone | 424.8 parts by mass |

In addition, the group adjacent to the acryloyloxy group in the following liquid crystalline compounds L-3 and L-4 represents a propylene group (a group in which a methyl group is substituted with an ethylene group), and the following liquid crystalline compounds L-3 and L-4 represent a mixture of positional isomers having different positions of the methyl group.

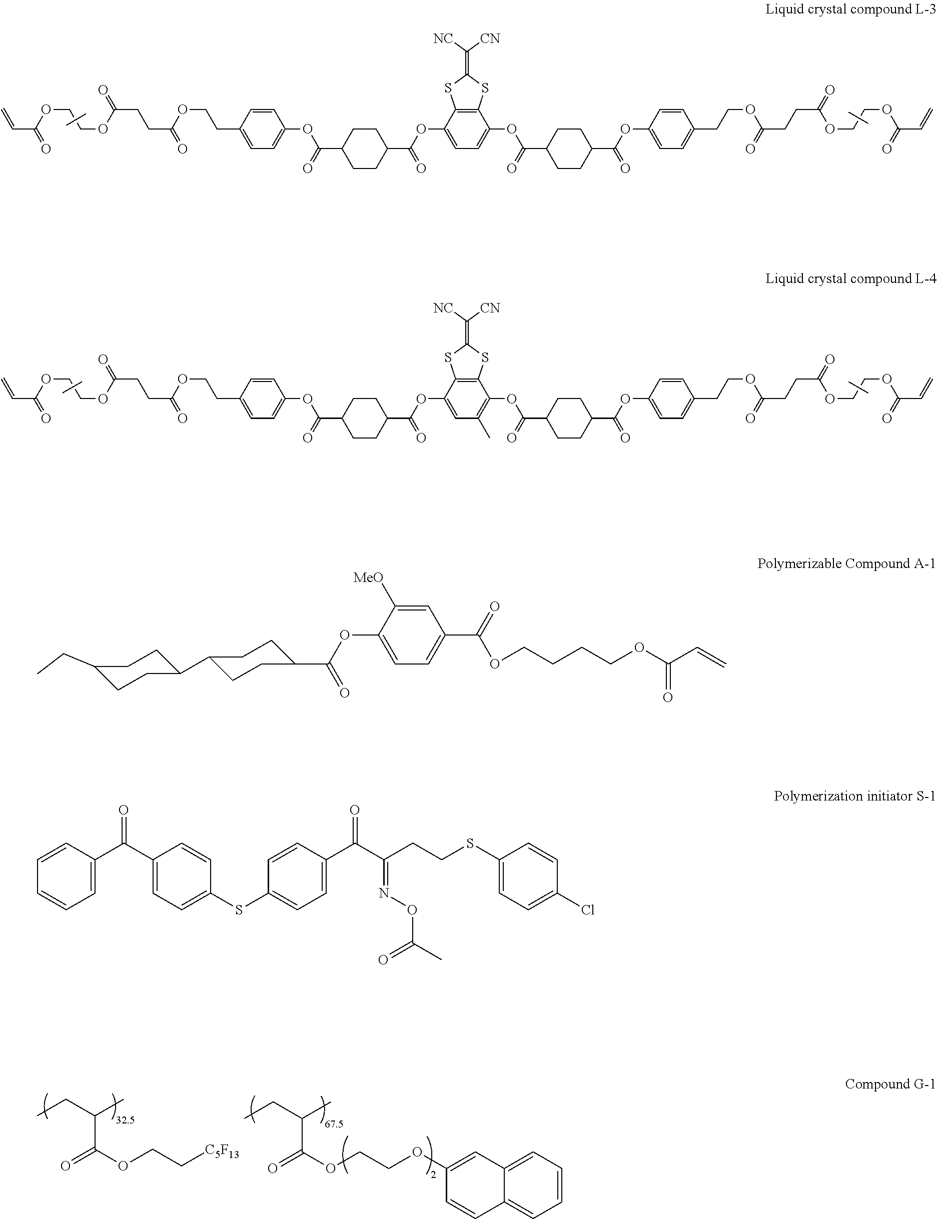

### Example 2, Comparative Example 1, and Comparative Example 3

Long phase difference films of Example 2, Comparative Example 1, and Comparative Example 3 were manufactured in the same manner as above, except that the long cellulose acylate films 2 to 4 were used in Example 1. The results are shown in Table 1.

### Example 3

A long phase difference film of Example 3 was manufactured in the same manner as in Example 1, except that the polymerizable liquid crystal composition was changed to the following liquid crystal 2 in Example 1. The results are shown in Table 1.

Coating liquid (liquid crystal 2) for optically anisotropic layer

| | | |
|---|---|---|
| The following liquid crystalline compound 4 | 100.0 | parts by mass |
| The polymerization initiator S-1 | 1.0 | part by mass |
| Leveling agent (Compound G-1) | 0.40 | parts by mass |
| Cyclopentanone | 259 | parts by mass |

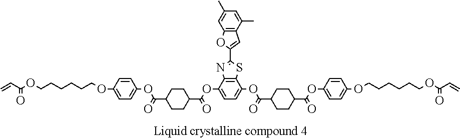 [SMILES: C=CC(=O)OCCCCCCOc1ccc(OC(=O)C2CCC(C(=O)Oc3ccc(OC(=O)C4CCC(C(=O)Oc5ccc(OCCCCCCOC(=O)C=C)cc5)CC4)c4sc(-c5cc6c(C)cc(C)cc6o5)nc34)CC2)cc1]

### Example 4

A long phase difference film of Example 4 was manufactured in the same manner as in Example 2, except that the irradiation amount of ultraviolet rays at the time of curing the liquid crystal layer by irradiation with ultraviolet rays was 150 mJ/cm². The results are shown in Table 1.

### Example 5

A long phase difference film of Example 5 was manufactured in the same manner as in Example 1, except that the coating liquid for the optically anisotropic layer was replaced with the liquid crystal 3 shown below, and the irradiation amount of ultraviolet rays at the time of curing the liquid crystal layer by irradiation with ultraviolet rays was 150 mJ/cm². The results are shown in Table 1.

Coating liquid (liquid crystal 3) for optically anisotropic layer

| | | |
|---|---|---|
| The following liquid crystalline compound L-3 | 42.00 | parts by mass |
| The following liquid crystalline compound L-4 | 42.00 | parts by mass |
| The following polymerizable compound A-1 | 16.00 | parts by mass |
| The following polymerizable compound B-1 | 6.00 | parts by mass |
| The following polymerization initiator S-1 | 0.50 | parts by mass |
| (oxime type) | | |
| Leveling agent (the following compound G-1) | 0.20 | parts by mass |
| High Solve MTEM (manufactured by Toho | 2.00 | parts by mass |
| Chemical Industry Co., Ltd.) | | |
| NK Ester A-200 (manufactured by Shin- | 1.00 | part by mass |
| Nakamura Chemical Co., Ltd.) | | |
| Methyl ethyl ketone | 424.8 | parts by mass |

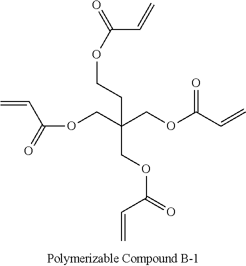 [SMILES: C=CC(=O)OCCC(COC(=O)C=C)(COC(=O)C=C)COC(=O)C=C]

### Example 6

A long phase difference film of Example 6 was manufactured in the same manner as in Example 5, except that the long cellulose acylate film 2 was used. The results are shown in Table 1.

### Examples 7, 8, and 9

Long phase difference films of Examples 7 to 9 were manufactured in the same manner as in Example 6, except that polymerizable compound B-1 in the polymerizable liquid crystal composition was replaced with B-2, B-3, and B-4. The results are shown in Table 1.

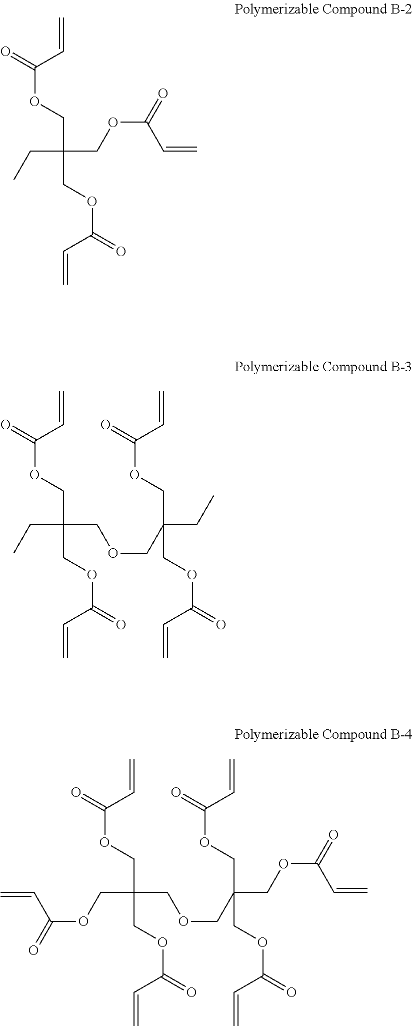 [SMILES: C=CC(=O)OCC(CC)(COC(=O)C=C)COC(=O)C=C ; C=CC(=O)OCC(CC)(COCC(CC)(COC(=O)C=C)COC(=O)C=C)COC(=O)C=C ; C=CC(=O)OCC(COCC(COC(=O)C=C)(COC(=O)C=C)COC(=O)C=C)(COC(=O)C=C)COC(=O)C=C]

### Example 10

A long phase difference film of Example 10 was manufactured in the same manner as in Example 2, except that a cellulose acetate film having a thickness of 15 μm was used as the cellulose acylate film, and the irradiation amount of ultraviolet rays at the time of curing the liquid crystal layer by irradiation with ultraviolet rays was 100 mJ/cm². The results are shown in Table 1.

### Comparative Example 2

A long phase difference film was manufactured in the same manner as in Comparative Example 1, except that the temperature at the time of curing the liquid crystal layer by irradiation with ultraviolet rays set to 75° C. in Comparative Example 1. The results are shown in Table 1.

Evaluations of the obtained support and phase difference film were performed as follows.

(Width-Direction Elastic Modulus)

The width-direction elastic modulus of the long support was measured in accordance with ISO 1184 1983, using a Tensilon tensile tester (trade name: RTA-100; manufactured by Orientec Co., Ltd.). Specifically, the elastic modulus was measured in an atmosphere of 25° C. and 60 RH % and the elastic modulus was calculated from the slope of a load-strain curve thus obtained. The elongation direction of the film sample was set to coincide with the width direction of the long support.

(Width-Direction Elastic Modulus at 140° C.)

A film sample in 5 mm×30 mm (with the longitudinal direction of the sample coinciding with the width direction of the long support) cut out from the long support film was conditioned at 25° C. and a relative humidity of 60% for 2 hours or more, then a dynamic viscoelasticity was measured with a dynamic viscoelasticity measuring device (Vibron: DVA-225 (manufactured by IT Keisoku Seigyo Co., Ltd.)) at a distance between grips of 20 mm, a temperature elevation rate of 2° C./min, a measuring temperature range of 30° C. to 250° C., and a frequency of 1 Hz, and a width-direction elastic modulus at 140° C. of the long support was determined from the storage elastic modulus at 140° C.

(Width-Direction Coefficient of Linear Thermal Expansion)

A film having a width of 3 mm and a length of 35 mm was cut out so that the longitudinal direction of the sample coincided with the width direction of the long support. The sample was conditioned in an environment of 25° C. and 60% RH for 3 hours or more, then a value ΔL (mm) measured by subtracting a dimension between chucks at 40° C. from a dimension between chucks at 80° C. of the sample was determined using a thermomechanical analyzer (TMA: manufactured by TA Instruments) at a distance between chucks of 25.4 mm, a temperature elevation condition of 30° C. to 100° C. (20° C./min) and a tension of 0.04 N, and ΔL/(25.4×10) was calculated to obtain a width-direction coefficient of linear thermal expansion of the long support.

(Liquid Crystal Alignment of Optically Anisotropic Layer)

A film having a width of 40 mm and a length of 40 mm was cut out from the obtained long phase difference film. The sample was observed with a polarizing microscope (using a 10× objective lens) under crossed Nicols to confirm the liquid crystal alignment.

A: No light leakage within the observation visual field. The optical pattern upon observation with an analyzer shifted by 40 from the crossed Nicols was uniform in the observation visual field.

B: Light leakage in the observation visual field. The optical pattern upon observation with an analyzer shifted by 40 from the crossed Nicols was non-uniform in the observation visual field (poor alignment was observed).

(Film Plane)

The obtained long phase difference film was unwound and allowed to stand on a horizontal plate, and surface conditions such as wrinkles, fold marks, and web distortion were visually confirmed. The distortion was confirmed by reflecting a rod-shaped fluorescent lamp and observing the reflected image.

A: A uniform and flat film without any of wrinkles, fold marks, and distortion was obtained.

B: Neither wrinkles nor fold marks were observed, but warping and distortion were observed in the film.

C: Clear wrinkles and bending marks were observed.

(In-Plane Phase Difference Change ΔRe of Phase Difference Film)

Each of the phase difference films cut into 7×14 cm² was conditioned in an environment of 25° C. and 60% RH for 3 hours or more, and then interposed between glass plates in the same size using a pressure-sensitive adhesive (JP2017-134414A, Example 1) from the both ends, and a retardation value (Rea) at a wavelength of 550 nm was measured using AxoScan (OPMF-1, manufactured by Axometrics). Thereafter, the sample was treated for 500 hours with a layer at a constant temperature and a constant humidity maintained at 85° C. and 0% RH, and then conditioned in an environment of 25° C. and 60% RH for 3 hours or more, an in-plane phase difference Reb(550) was measured with AxoScan, and an in-plane phase difference change rate ΔRe=Reb/Rea was quantified from the change rate.

A: ΔRe=0.98 or more and 1.01 or less

B: ΔRe=0.96 or more and less than 0.98, and more than 1.01 and 1.02 or less

C: ΔRe=0.94 or more and less than 0.96

D: ΔRe=less than 0.94 and more than 1.02

(Evaluation of OLED Panel Mounting)

The obtained phase difference film 1 of Example 1 was bonded to a long linear polarizing plate (with the absorption axis being in the longitudinal direction) by a roll-to-roll process in such a manner that the cellulose acylate film side of the phase difference film was used as the polarizing plate side and the cellulose acylate film 1 also served as the polarizing plate protective film, and then wound up once to manufacture a long laminate of the embodiment of the present invention. Further, the long laminate was unwound and cut into a predetermined shape to obtain a circularly polarizing plate 1. The positive C-plate described in paragraphs 0124 to 0127 of Examples in JP2015-200861A (provided that the thickness of the positive C-plate was controlled so that Rth at 550 nm was −65 nm) was transferred and bonded onto a surface of the phase difference film side of the obtained circularly polarizing plate 1 to obtain a laminate 1. The angle between the in-plane slow axis of the phase difference film and the transmission axis of the linearly polarizing plate was 45°.

Next, GALAXY SII manufactured by SAMSUNG having an organic EL panel mounted therein was disassembled, the circularly polarizing plate was peeled off, and a laminate piece cut out from the laminate 1 manufactured above so as to have the same shape and the same transmission axis direction as those of the circularly polarizing plate taken out was bonded thereto via a pressure-sensitive adhesive so that the positive C-plate side became the panel side, thereby manufacturing an OLED display device 1. Upon observation of the obtained OLED display device under natural light in a black display state, it showed no unevenness in both the front direction and the oblique direction and good black display performance (Evaluation: A).

Next, a laminate 11 was manufactured by performing the same operation as described above, except that the phase difference film 11 obtained in Comparative Example 1 was used instead of the phase difference film 1, a laminate piece cut out from the laminate 11 was mounted on an organic EL panel and evaluated, and thus, streaky color unevenness was observed on the panel during black display (Evaluation: C).

(Evaluation of Durability in OLED Panel Mounting)

With respect to each of the phase difference films 2 to 10 obtained in Examples 2 to 10 and the phase difference films 12 and 13 obtained in Comparative Examples 2 and 3, a laminate was manufactured in the same manner as described above, and a laminate piece cut out from the laminate was mounted on an organic EL panel.

A glass plate was bonded onto the organic EL panel mounted therewith via a pressure-sensitive adhesive and treated for 500 hours in a layer at a constant temperature and a constant humidity maintained at 85° C. and 0% RH, and then conditioned in an environment of 25° C. and 60% RH for 3 hours or more, and the appearance was observed under natural light in a black display state.

A: Reddish unevenness was not observed and good black display performance was exhibited.

B: Weak unevenness was observed at a panel edge.

C: Strong unevenness was observed at a panel edge.

D: Reddish unevenness was observed on the entire surface.

The results are shown in Tables 1 and 2.

TABLE 1

| | Long support | | | | | | | | | | |
|---|---|---|---|---|---|---|---|---|---|---|---|
| | | Width-direction | | Width-direction | Optically anisotropic layer | | | Condition for UV curing of optically | | | |
| | Width-direction | elastic modulus | | coefficient of linear | Type of polymerizable | Type of | | anisotropic layer | | Phase difference film | |
| | elastic modulus | 140° C. | Thickness | thermal expansion | liquid crystal | polymcrizable | Wavelength | Temperature | Irradiation amount | Thickness | In-plane phase difference |
| | [Gpa] | [Gpa] | [μm] | [ppm/° C.] | compound | compound | dispersion | [° C.] | [mJ/cm²] | [μm] | change rate ΔRe |
| Example 1 | 4.6 | 1.8 | 40 | 35 | L-3, 4 | A-1 | 0.87 | 120 | 300 | 43 | B |
| Example 2 | 5.0 | 2.0 | 20 | 33 | L-3, 4 | A-1 | 0.87 | 120 | 300 | 23 | B |
| Example 3 | 4.6 | 1.8 | 40 | 35 | Liquid crystal-4 | — | 0.87 | 120 | 300 | 43 | B |
| Example 4 | 5.0 | 2.0 | 20 | 33 | L-3, 4 | A-1, B-1 | 0.87 | 120 | 150 | 23 | C |
| Example 5 | 4.6 | 1.8 | 40 | 35 | L-3, 4 | A-1, B-1 | 0.87 | 120 | 150 | 43 | A |
| Example 6 | 5.0 | 2.0 | 20 | 33 | L-3, 4 | A-1, B-2 | 0.87 | 120 | 150 | 23 | A |
| Example 7 | 5.0 | 2.0 | 20 | 33 | L-3, 4 | A-1, B-3 | 0.87 | 120 | 150 | 23 | A |
| Example 8 | 5.0 | 2.0 | 20 | 33 | L-3, 4 | A-1, B-4 | 0.87 | 120 | 150 | 23 | A |
| Example 9 | 5.0 | 2.0 | 20 | 33 | L-3, 4 | A-1 | 0.87 | 120 | 150 | 23 | A |
| Example 10 | 5.0 | 2.0 | 15 | 33 | L-3, 4 | A-1 | 0.87 | 120 | 100 | 18 | B |
| Comparative | 3.7 | 1.0 | 40 | 52 | L-3, 4 | A-1 | 0.87 | 120 | 300 | 43 | — |
| Example 1 | | | | | | | | | | | |
| Comparative | 3.7 | 1.0 | 40 | 52 | L-3, 4 | A-1 | 0.87 | 120 | 300 | 43 | D |
| Example 2 | 1 | | | | | | | | | | |
| Comparative | 3.7 | 1.0 | 60 | 52 | L-3, 4 | A-1 | 0.87 | 120 | 300 | 63 | B |
| Example 3 | | | | | | | | | | | |

TABLE 2

| | Evaluation results | | | |
|---|---|---|---|---|
| | | | Evaluation | Durability in |
| | Liquid | Film | of OLED | Mounting |
| | crystal | plane | panel | (Reddish |
| | alignment | state | mounting | unevenness) |
| Example 1 | A | A | A | B |
| Example 2 | A | B | — | B |
| Example 3 | A | A | — | B |
| Example 4 | A | A | — | C |
| Example 5 | A | A | — | A |
| Example 6 | A | A | — | A |
| Example 7 | A | A | — | A |
| Example 8 | A | A | — | A |
| Example 9 | A | A | — | A |
| Example 10 | A | B | — | B |
| Comparative | B | C | C | C |
| Example 1 | | (wrinkles) | | |
| Comparative | A | A | — | D |
| Example 2 | | | | |
| Comparative | B | A | — | B |
| Example 3 | | | | |

From Tables 1 and 2, it was found that in Examples in which the thickness, the width-direction elastic modulus, the width-direction coefficient of linear thermal expansion, and the in-plane phase difference change ΔRe of the long support were within the range of the present invention, the liquid crystal alignment was uniform, the film plane state was uniform, and reddish unevenness was little, as compared with Comparative Examples.

Furthermore, from the comparison of Example 1, Example 2, and Example 10, it was found that the thickness of the support was preferably 15 μm or more.

In addition, from the comparison of Example 2, Example 4, and Examples 6 to 9, it was found that the in-plane phase difference change ΔRe was preferably from 0.96 to 1.02, and more preferably from 0.98 to 1.01.

From the above, the effect of the present invention is apparent.

What is claimed is:

1. A long phase difference film comprising:
a long support formed of a resin film; and
a long optically anisotropic layer arranged on one surface side of the long support,
wherein the long support has a thickness of 10 μm to 50 μm, a width-direction elastic modulus of 4.3 GPa to 6.0 GPa, and a width-direction coefficient of linear thermal expansion of 10 ppm/° C. to 35 ppm/° C.,
the optically anisotropic layer is formed of a polymerizable liquid crystal composition including a polymerizable liquid crystal compound having reciprocal wavelength dispersion, and
an in-plane phase difference change ΔRe at the time of treating the long phase difference film under a heating condition of 85° C. and 500 hours is 0.94 to 1.02.

2. The long phase difference film according to claim 1,
wherein a width-direction elastic modulus at 140° C. of the long support is 1.5 GPa to 3.0 GPa.

3. The long phase difference film according to claim 1,
wherein an Re(550) and an Rth(550) of the long support are 0 nm to 10 nm and −20 nm to 40 nm, respectively.

4. The long phase difference film according to claim 1, comprising:
an alignment layer between the long support and the optically anisotropic layer, the alignment layer being in contact with the optically anisotropic layer.

5. The long phase difference film according to claim 1,
wherein an Re(550) of the optically anisotropic layer is 100 nm to 250 nm.

6. The long phase difference film according to claim 5,
wherein an Re(550) of the optically anisotropic layer is 100 nm to 160 nm and an in-plane slow axis of the optically anisotropic layer forms an angle of 300 to 500 with respect to a longitudinal direction of the long support.

7. The long phase difference film according to claim 1,
wherein the optically anisotropic layer is in contact with the long support, or
an alignment layer is included between the long support and the optically anisotropic layer, the alignment layer being in contact with the optically anisotropic layer, and
the optically anisotropic layer is provided to be peelable.

8. A long laminate formed by laminating the long phase difference film according to claim 1 and a long linearly polarizing film.

9. An image display device comprising:
a polarizing plate cut out from the long laminate according to claim 8.

10. The long phase difference film according to claim 2,
wherein an Re(550) and an Rth(550) of the long support are 0 nm to 10 nm and −20 nm to 40 nm, respectively.

11. The long phase difference film according to claim 2, comprising:
an alignment layer between the long support and the optically anisotropic layer, the alignment layer being in contact with the optically anisotropic layer.

12. The long phase difference film according to claim 3, comprising:
an alignment layer between the long support and the optically anisotropic layer, the alignment layer being in contact with the optically anisotropic layer.

13. The long phase difference film according to claim 2,
wherein an Re(550) of the optically anisotropic layer is 100 nm to 250 nm.

14. The long phase difference film according to claim 3,
wherein an Re(550) of the optically anisotropic layer is 100 nm to 250 nm.

15. The long phase difference film according to claim 4,
wherein an Re(550) of the optically anisotropic layer is 100 nm to 250 nm.

16. The long phase difference film according to claim 2,
wherein the optically anisotropic layer is in contact with the long support, or
an alignment layer is included between the long support and the optically anisotropic layer, the alignment layer being in contact with the optically anisotropic layer, and
the optically anisotropic layer is provided to be peelable.

17. The long phase difference film according to claim 3,
wherein the optically anisotropic layer is in contact with the long support, or
an alignment layer is included between the long support and the optically anisotropic layer, the alignment layer being in contact with the optically anisotropic layer, and
the optically anisotropic layer is provided to be peelable.

18. The long phase difference film according to claim 4,
wherein the optically anisotropic layer is in contact with the long support, or
an alignment layer is included between the long support and the optically anisotropic layer, the alignment layer being in contact with the optically anisotropic layer, and
the optically anisotropic layer is provided to be peelable.

19. The long phase difference film according to claim 5,
wherein the optically anisotropic layer is in contact with the long support, or
an alignment layer is included between the long support and the optically anisotropic layer, the alignment layer being in contact with the optically anisotropic layer, and
the optically anisotropic layer is provided to be peelable.

20. The long phase difference film according to claim 6,
wherein the optically anisotropic layer is in contact with the long support, or
an alignment layer is included between the long support and the optically anisotropic layer, the alignment layer being in contact with the optically anisotropic layer, and
the optically anisotropic layer is provided to be peelable.
